(19) United States
(12) Patent Application Publication
(10) Pub. No.: US 2025/0079066 A1
(43) Pub. Date: Mar. 6, 2025

(54) SYSTEMS, DEVICES, AND METHODS FOR INTEGRATED VOLTAGE REGULATORS

(71) Applicant: Murata Manufacturing Co., Ltd., Kyoto (JP)

(72) Inventors: KOUASSI Sebastien KOUASSI, San Diego, CA (US); David GIULIANO, Bedford, NH (US)

(21) Appl. No.: 18/694,876

(22) PCT Filed: Sep. 23, 2022
(86) PCT No.: PCT/US2022/076960

§ 371 Date: Mar. 22, 2024

Related U.S. Application Data
(60) Provisional application No. 63/247,728, filed on Sep. 23, 2021.
(60) Provisional application No. 63/316,059, filed on Mar. 3, 2022.

(51) Int. Cl. H01F 27/28; H01F 27/24; H01F 27/40; H01G 4/30; H02M 3/00; H02M 7/00

(52) U.S. Cl. CPC H01F 27/28; H01F 27/24; H01F 27/40; H01G 4/30; H02M 3/003; H02M 7/003

(57) ABSTRACT

Disclosed embodiments may include systems, devices and methods for fabricating high-density charge-storage devices and power conversion devices. In one embodiment, a device is disclosed, comprising an inductor. The inductor includes a first inductor surface and a second inductor surface opposite the first inductor surface. The inductor further includes a first inductor substrate including a cavity. A seed layer is formed on a bottom surface of the cavity, and a magnetic layer is formed on the seed layer. The magnetic layer includes a plurality of stacked magnetic layers separated from each other by an insulating material layer.

### PRIORITY CLAIM

The present application claims priority under 35 U.S.C. § 119 to U.S. Provisional Patent Application No. 63/247,728, filed Sep. 23, 2021, titled “SYSTEMS, DEVICES, AND METHODS FOR HIGH-DENSITY POWER CONVERTERS,” and U.S. Provisional Patent Application No. 63/316,059, filed Mar. 3, 2022, titled “SYSTEMS, DEVICES, AND METHODS FOR INTEGRATED VOLTAGE REGULATORS.” The entire contents of the aforementioned applications are incorporated herein by reference for all purposes.

### TECHNICAL FIELD

The present disclosure generally relates to voltage converters and/or regulator devices. More particularly, the present disclosure relates to systems and methods of fabricating integrated voltage converters and/or regulators.

### BACKGROUND

With the advancements in integrated circuit technologies and computing capabilities, there is a commensurate growth in the demand for integrated power conversion, regulation, and its management. Power management circuits of most portable electronic devices and consumer electronics rely on power converters, and more typically DC-DC power converters, to accomplish energy transfer and voltage conversion to a desired voltage level. For example, radio frequency transmitter power amplifiers may require relatively high voltages (e.g., 12V or more), and logic circuitry may require a low voltage level (e.g., 1-2V). Some other circuitry may require an intermediate voltage level (e.g., 5-10V).

### SUMMARY

Embodiments of this disclosure provide systems and methods for fabricating high-density charge-storage devices and power conversion devices. One aspect of this disclosure is directed to a power conversion device. The device may include a substrate including a cavity, a seed layer formed on a bottom surface of the cavity, a magnetic layer formed on the seed layer, wherein the magnetic layer includes a plurality of stacked magnetic layers separated from each other by a dielectric layer.

Another aspect of this disclosure is directed to a method of forming a device. The method may include forming a cavity in a substrate, depositing a seed layer on a bottom surface of the cavity, and depositing a magnetic layer on the seed layer, wherein the magnetic layer includes a plurality of stacked magnetic layers separated from each other by a dielectric layer.

Another aspect of this disclosure is directed to a power conversion device. The device may include a substrate including a cavity, a first seed layer formed on a bottom surface of the cavity, a magnetic layer formed on the first seed layer, and a second seed layer formed on the magnetic layer and electrically connected to the first seed layer such that the first and the second seed layer form a winding around the magnetic layer.

Another aspect of this disclosure is directed to a device. The device may include a charge-storage device, including a first substrate including a first surface and a second surface opposite the first surface, a first plurality of conductive structures that extend vertically from the first surface toward the second surface, a second plurality of conductive structures that extend vertically from the second surface toward the first surface, a first dielectric material physically separating the first and the second plurality of conductive structures, wherein the first and the second plurality of conductive structures are interdigitated, and a magnetic device. The magnetic device may include a second substrate comprising a cavity, a seed layer formed on a bottom surface of the cavity, and a magnetic layer formed on the seed layer, wherein the magnetic layer comprises a plurality of stacked magnetic layers separated from each other by a second dielectric material, wherein the charge-storage device and the magnetic device are bonded to each other.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIGS. 1A, 1B, and 1C are schematic illustrations of a cross-section view, a bottom plan view, and a bottom perspective view, respectively, of an exemplary inductor supported by a substrate, in accordance with some embodiments of the present disclosure.

FIGS. 2A and 2B are schematic illustrations of a top plan view and a perspective view respectively, of an exemplary toroidal inductor, in accordance with some embodiments of the present disclosure.

FIGS. 3A and 3B are schematic illustrations of a cross-section view and a circuit representation of an exemplary LC (inductor-capacitor) network featuring a capacitor and an inductor connected in series, in accordance with embodiments of the present disclosure.

FIG. 3C is a schematic illustration of a cross-section view of an exemplary power converter featuring a capacitor and an inductor connected in series, in accordance with embodiments of the present disclosure.

FIG. 4 is a schematic illustration of a cross-section view of an exemplary LC network featuring a capacitor and an inductor connected in series, in accordance with embodiments of the present disclosure.

FIG. 5 is a schematic illustration of a cross-section view of an exemplary LC network featuring two capacitors and an inductor, in accordance with embodiments of the present disclosure.

FIG. 6 is a schematic illustration of a cross-section view of an exemplary LC network featuring two inductors and a capacitor, in accordance with embodiments of the present disclosure.

FIG. 7 is a schematic illustration of a cross-section view of an exemplary LC network featuring two inductors and a capacitor connected in parallel, in accordance with embodiments of the present disclosure.

FIG. 8A is a schematic illustration of a cross-section view of an exemplary power converter including an active device layer and a capacitor layer, in accordance with embodiments of the present disclosure.

FIG. 8B is a schematic illustration of a top plan view of an exemplary capacitor layer of FIG. 8A including a capacitor array, in accordance with embodiments of the present disclosure.

FIG. 8C is a schematic illustration of a circuit representation of a multi-level buck converter exemplified in FIGS. 8A and 8B, in accordance with embodiments of the present disclosure.

FIGS. 9A and 9B illustrate cross-section views of exemplary power converter of FIGS. 8A-8C through fabrication steps, in accordance with embodiments of the present disclosure.

FIGS. 10A and 10C illustrates a schematic of a cross-section view of an exemplary power converter featuring active devices, capacitors, and inductors, in accordance with some embodiments of the present disclosure.

FIG. 10B illustrates a schematic of a bottom plan view of an inductor layer of FIG. 10A, in accordance with some embodiments of the present disclosure.

FIGS. 11A and 11B illustrate cross-section views of reconstituted wafers featuring an example power converter, in accordance with some embodiments of the present disclosure.

### DETAILED DESCRIPTION

The following disclosure provides many different exemplary embodiments, or examples, for implementing different features of the provided subject matter. Specific simplified examples of components and arrangements are described below to explain the present disclosure. These are, of course, mere examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the 15 term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other or maintain an electrical continuity between each other.

Some embodiments of the invention may allow implementation of better passive components in a power converter that may in turn ease the performance requirements on the active components such as switch components.

Various non-limiting embodiments of the present disclosure will be described with respect to embodiments in a specific context, namely a high-density and high-efficiency voltage regulation device. As used in this disclosure, the term “voltage regulator” refers to a component of the power supply unit (PSU) configured to convert an input voltage to a stable output voltage. While most voltage regulators may be used for DC-DC power conversion, some voltage regulators may be used for AC-DC or AC-AC power conversion as well. A linear voltage regulator may be configured to output a lower, stable voltage signal from a higher voltage signal. In some cases, a linear voltage regulator may utilize an input and an output capacitor, or an active pass device, such as a bipolar junction transistor (BJT) or a metal-oxide semiconductor field effect transistor (MOSFET), to regulate the voltage. A switching voltage regulator, however, may be configured as a Step-Down (buck converter), a Step-Up (Boost converter), or a Buck-Boost Converter, with the help of additional external components, such as inductors, capacitors, FETs, or feedback resistors.

A voltage regulator may serve as a power converter. The concepts in the disclosure may apply to voltage regulators or power converters. Power converters which convert a higher input voltage power source to a lower output voltage level may be referred to as step-down or buck converters, because the converter is “bucking” the input voltage. Power converters which convert a lower input voltage power source to a higher output voltage level may be referred to as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments of the present disclosure, a power converter may be bi-directional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

Voltage regulators, such as switching voltage regulators, may rely in part on capacitors and inductors to fulfil the power conversion requirements. The inventors here have recognized, however, that existing capacitors and inductors may suffer from drawbacks such as bulkiness, efficiency losses, and reduced power densities with shrinking geometries. Existing capacitors and inductors may also pose integration challenges during fabrication of such power conversion devices. For example, as the overall dimensions of the inductors shrink, it may be desirable to have inductors with higher saturation flux density, lower core losses, and high relative permeability to allow higher current density through the inductors. Although a magnetic alloy having one or more of these characteristics may be electroplated on a silicon (Si) substrate, it may be undesirable to do so because the electroplating process may introduce tensile or compressive stress, causing the substrate to warp, among other limiting issues, such as those specific to design constraints for portable electronic devices. In some structures, arrays of voltage regulators and/or power converters may have to be small enough to be separately placed in close proximity to microprocessors, for example, for reduction in parasitics and in overall form factor, by using smaller magnetics and compact integrated capacitors. Certain disclosed embodiments may address these and other challenges.

Voltage regulators and power converters that use capacitors to transfer energy may have certain disadvantages when packaged in the traditional manner. For example, when packaged in the traditional manner, there may be high parasitic resistance and high parasitic inductance due to the distance between switches and capacitors. Additionally, the power density of voltage regulators and power converters packaged in the traditional manner may be limited by the surface area of the silicon and the size of the devices implemented on the silicon.

Various embodiments of the present disclosure address these issues by packaging voltage regulators and power converters in three-dimensions. Devices packaged in three-dimensions may lower parasitic resistance and parasitic inductance when compared to devices packaged in the traditional manner because devices packaged in three-dimensions can be stacked on top of one another. Stacking devices on top of one another and connecting them via through silicon vias can reduce the distance between components and thereby reduces the parasitic resistance and inductance. Additionally, devices packaged in three-dimensions may have increased power density when compared to those packaged in the traditional manner, especially when implemented in portable electronic devices such as tablets, cell phones, or hand-held computers, and IoT (Internet of Things) devices. In three-dimensionally packaged devices, areal power density (i.e., W/mm²) can be increased in the same manner areal power density is increased in traditionally packaged devices (e.g., by decreasing the area of the silicon and/or passives). However, devices packaged in three dimensions can also be stacked to areal increase power density. Therefore, devices packaged in three-dimensions may have a higher number of components on a given area than traditionally packaged devices.

Voltage regulators and power converters packaged in three-dimensions also can have improved modularity when compared to those packaged in the traditional manner. For example, components may be integrated in the three-dimensional structure to increase the overall power of the device (e.g., by stacking charge pumps). Additionally, packaging voltage regulators and power converters in three-dimensions may allow passive components and power switches to be implemented on the same wafer as hybrid devices (e.g., adiabatic charge pumps and multi-level charge pumps).

In some embodiments utilizing three-dimensional packaging, additional active device layers may be stacked on top of one another. Active devices layers can be stacked to form tunable filters. Tunable filters can have one or more active switch devices for varying the values of both the capacitors and the inductors.

Active devices may also be stacked to form fully integrated voltage regulators. Fully integrated voltage regulators may be arrays of voltage regulators or power converters that are positioned relatively close to the microprocessor and are used to provide different power levels to different parts of the microprocessor. Typically, fully integrated voltage regulators may be implemented on two separate dies to reduce parasitic resistance and inductance and the reduce the total area of the fully integrated voltage regulator. When implemented using three-dimensional packaging, the fully integrated voltage regulators can use multi-level converters that allow for a wider voltage range than fully integrated voltage regulators packaged in the traditional manner. A higher efficiency may be achieved by decreasing the parasitic resistance and parasitic inductance of the device and increasing the size of the integrated capacitors. This can be achieved using three-dimensional packaging.

In various embodiments of the present disclosure, systems and methods of fabricating high-density voltage regulators or power converters may be disclosed. The disclosed wafer-based/panel-based integration methods can provide high power density with high magnetic flux density and low eddy current losses. The high density, integrated voltage regulators/power converters may be desirable in applications including, but not limited to, portable electronic devices such as tablets, cell phones, or hand-held computers, and IoT (Internet of Things) devices.

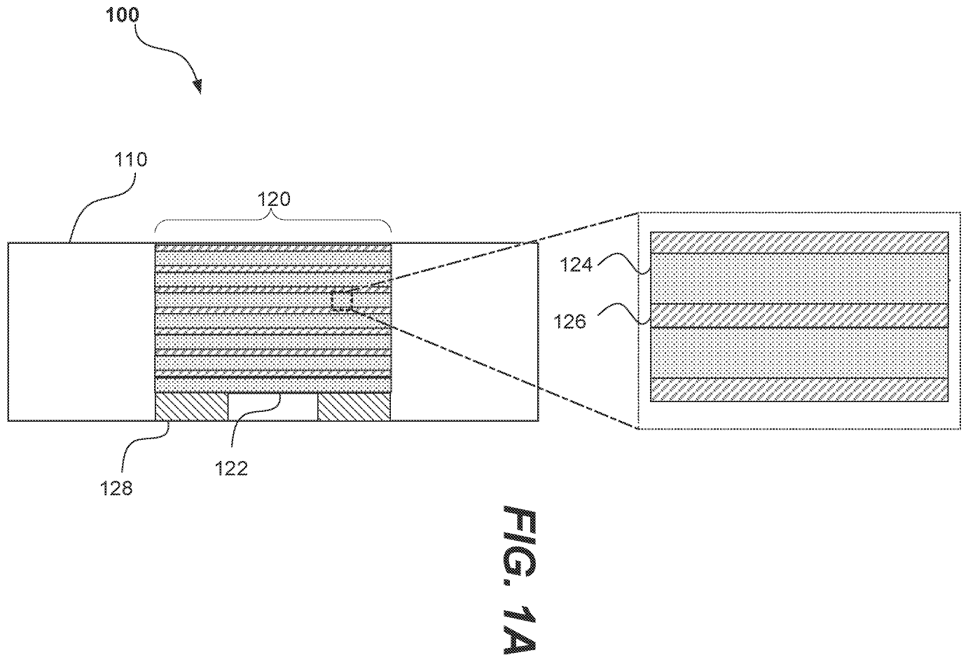

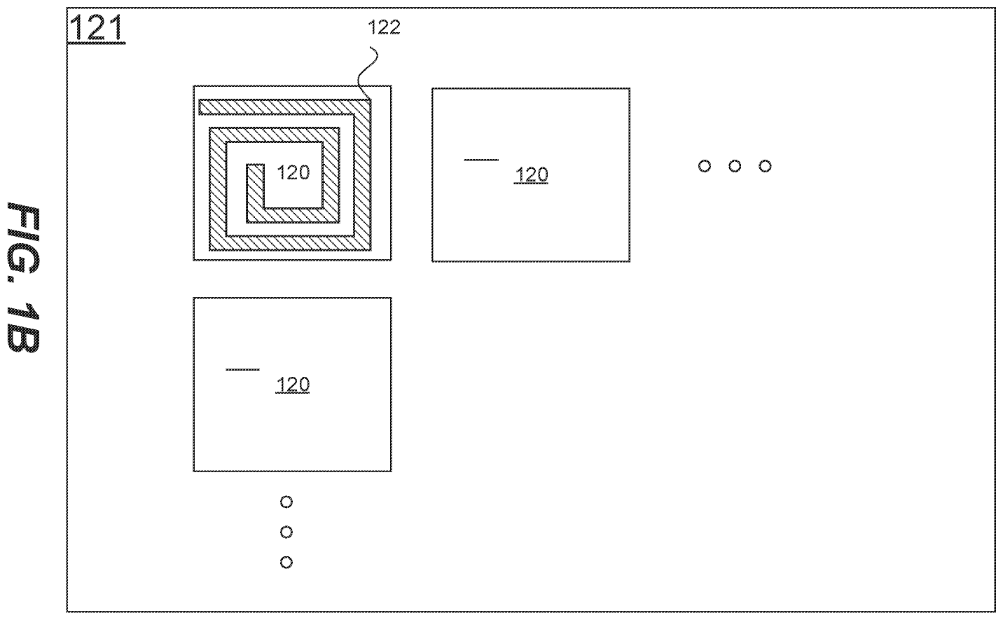

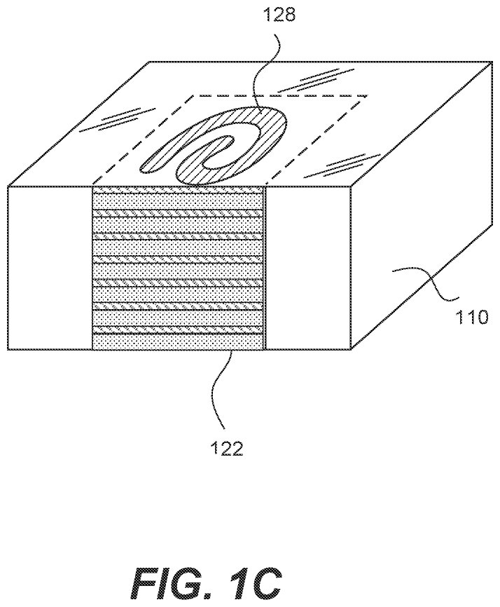

Reference is now made to FIGS. 1A-1C, which are schematic illustrations of an exemplary magnetic component, such as an inductor, in accordance with some embodiments of the present disclosure. FIG. 1A shows a cross-section view 100 of an exemplary inductor 120 formed within a substrate 110. In some embodiments, substrate 110 may include a wafer made of an electrically insulating material such as, but not limited to, a ceramic (alumina, aluminum nitride, sapphire, quartz, etc.), a polymer, a composite, or glass. Substrate 110 may be used as a template, for example, by forming trenches and depositing magnetic materials (e.g., by electroplating or squeegeeing a magnetic paste) to form an array of inductors 120. In addition to being used as a template, substrate 110 may provide structural support to one or more inductors 120 formed therein, among other functionalities. The structural support, in the context of this disclosure, may be attributed to the mechanical rigidity of the substrate and its ability to withstand tensile or compressive stress during fabrication. In a preferred embodiment, substrate 110 may be a glass substrate or a glass wafer.

As shown in cross-section view 100 in FIG. 1A, an exemplary inductor 120 formed within a glass substrate 110 may include a laminated core 122 and a coil 128. In some embodiments, a trench or a cavity may be formed in substrate 110 by a material removal process such as, but not limited to, wet-etching, plasma etching, laser etching, machining, or a CMOS compatible etch process including photolithography, or a combination thereof. In some embodiments, coil 128 may include a spirally wound coil made of an electrically conducting material such as, but not limited to, copper, aluminum, silver, titanium, an alloy, or other suitable electrically conducting materials. In a preferred embodiment, coil 128 may be made of copper. Coil 128 may be formed on a bottom surface of the cavity in substrate 110. Although not illustrated in FIG. 1A, it is to be appreciated that substrate 110 may include more than one inductors 120.

In some embodiments, laminated core 122 may include an alternating stack of magnetic material layers 124 separated by insulating material layers 126. Laminated core 122 may be formed on coil 128 such that at least a portion of laminated core 122 is in physical contact with coil 128. An exploded view of an exemplary arrangement of magnetic material layers 124 separated by insulating material layers 126 is illustrated in FIG. 1A. Magnetic material layer 124 may include a NiFe (nickel-iron) alloy, a NiCo (nickel-cobalt) alloy, or a suitable soft-magnetic alloy material. In some embodiments, magnetic material layer 124 may be formed by, for example, electroplating, coating, spraying, doctor-blading, squeegeeing, or other suitable techniques of forming a soft magnetic layer such that the desirable magnetic properties may be retained. Insulating material layer 126 may include a dielectric, a polymer, a ceramic, or any material capable of providing electrical insulation between two adjacent magnetic material layers 124. In some embodiments, insulating material layer 126 may be formed by, for example, coating, spraying, doctor blading, or other suitable deposition techniques. The individual layer thicknesses of magnetic material layer 124 and insulating material layer 126 may be adjusted based on desired properties of inductor 120.

In some embodiments, inductor 120 may be formed within substrate 110 such that at least a portion of inductor 120 may be supported by substrate 110. In a preferred embodiment, inductor 120 may be formed in the cavity in substrate 110 such that the entirety of inductor 120 is structurally supported by substrate 110.

FIG. 1B illustrates a bottom plan view of an inductor array 121 including a two-dimensional matrix of inductors 120 and FIG. 1C illustrates a bottom perspective view of inductor 120, consistent with embodiments of the present disclosure. In some embodiments, inductors 120 of inductor array 121 may be spaced uniformly or non-uniformly apart in the horizontal direction, or inductors 120 may be spaced uniformly or non-uniformly apart in the vertical direction, or in an arrangement including any combination thereof. In some embodiments, inductor array 121 may include a rectangular matrix or a square matrix of inductors 120.

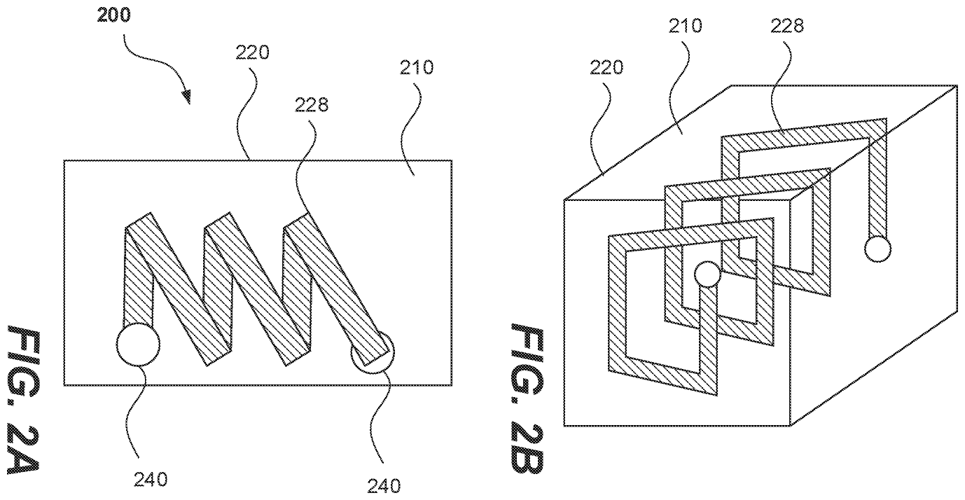

Reference is now made to FIGS. 2A and 2B, which are schematic illustrations of an exemplary toroidal inductor, consistent with some embodiments of the present disclosure. FIG. 2A shows a top plan view 200 of an exemplary toroidal inductor 220 formed within a substrate 210. In some embodiments, substrate 210 may include a wafer made of an electrically insulating material such as, but not limited to, a ceramic (alumina, aluminum nitride, sapphire, quartz, etc.), a polymer, a composite, or glass. Substrate 210 may be used as a template, for example, by forming trenches and depositing magnetic materials to form an array of inductors 220. FIG. 2B illustrates a perspective view of toroidal inductor 220 shown in FIG. 2A.

In some embodiments, toroidal inductor 220 may comprise terminals 240 configured to provide electrical connection between inductor 220 and other components of the power converter device such as, a capacitor (not shown), or a transistor (not shown), for example. Terminal 240 may include a contact pad, an electrode, or an electrical terminal to maintain electrical continuity within layers of a power converter device. Although shown as a rectangular winding in FIG. 2B, it is to be appreciated that other form factors and geometries may be possible as well, such as a circular spiral or an elliptical spiral.

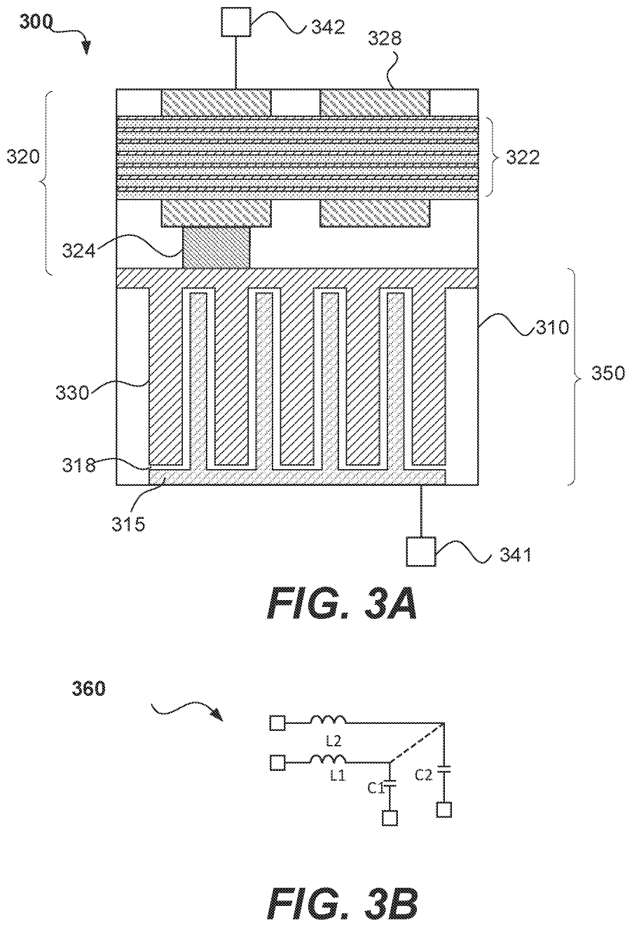

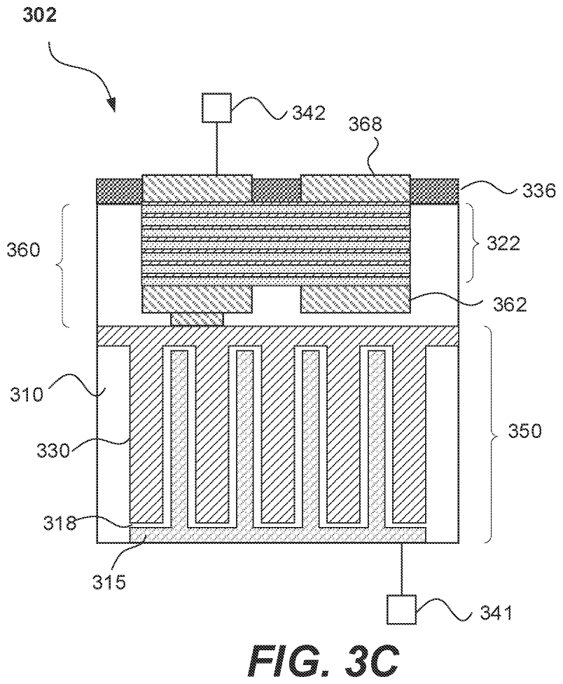

Reference is now made to FIG. 3A, which illustrates a cross-section view of an exemplary LC network 300 featuring a capacitor and an inductor connected in series, consistent with some embodiments of the present disclosure. LC network 300 may include an inductor 320, a capacitor 350, and terminals 341 and 342. FIG. 3B illustrates a representative circuit diagram of a LC (inductor-capacitor) network array, e.g., a LC filter array, showing inductors L1 and L2 connected in series with capacitors C1 and C2, respectively. While the cross-section shown in FIG. 3A only depicts a single capacitor connected to a single inductor (forming a single L-C filter) via a connection 324, the components of that cross-section may be repeated through the substrate, forming multiple L-C networks or filters in a line or grid or an array, as shown in FIG. 3B. It is to be appreciated that although LC network 300 includes an array of interdigitated capacitors, in the context of this disclosure, it may be collectively referred to as “a capacitor.”

In the exemplary embodiment shown in FIG. 3A, inductor 320 may be a toroidal inductor comprising a coil 328 wound around a laminated core 322. It is to be appreciated, however, that other configurations of inductors may be used as well. Inductor 320 may be substantially similar to inductor 220 of FIGS. 2A and 2B and may perform substantially similar functions. Although not shown in FIG. 3A, upper and lower windings of coil 328 may be electrically connected through one or more vias formed in laminated core 322. Terminal 342 may provide an electrical continuity between inductor 320 and external circuitry such as, a power supply unit, a controller, or the like.

LC network 300 may further include capacitor 350. In some embodiments, capacitor 350 may be fabricated in a substrate 310 and may include interdigitated conductive structures 315 and 330, physically separated by a dielectric layer 318. In some embodiments, substrate 310 may be glass, photosensitive glass, quartz, silicon, SOI, SOG, SOQ, ceramic, GaAs, GaN, or other material amenable to semiconductor processing techniques, and may provide a support for the capacitor structures. Substrate 310 may have a thickness ranging from 50 μm to 100 μm, 50 μm to 200 μm, 50 μm to 300 μm, 50 μm to 400 μm, 50 μm to 500 μm, 50 μm to 1 mm, or a thickness suitable based on the application, structures fabricated therein, processing limitations, or a combination thereof. In the embodiment shown in FIG. 3A, substrate 310 may be a photosensitive glass having a thickness of 400±20 μm.

In the embodiment shown in FIG. 3A, three-dimensional structures may be formed in substrate 310 by exposing substrate 310 with an ultraviolet radiation having a wavelength ranging from 280 nm to 320 nm, through a patterned mask, followed by baking and etching. The characteristics of the exposure radiation may be adjusted to vary the dimensions of the three-dimensional structures being formed. For example, trenches may be formed in substrate 310 and an aspect ratio of the trenches may be adjusted by adjusting one or more of the energy, radiation intensity, exposure duration, radiation wavelength, and other characteristics of the exposing radiation. The exposed regions of substrate 310 may be structurally and atomically modified such that the exposed regions of substrate 310 may be etched using a physical or chemical etch process. A person of ordinary skill in the art would appreciate that isotropicity of the etch process may depend on the etchant and/or material being etched. For example, physical or dry etch processes may generally result in anisotropic etching, and chemical or wet etches generally produce isotropic etching.

In some embodiments, the trenches formed in substrate 310 may be metallized to form conductive structures 315. For example, the trenches may be metallized by electrolytic plating, electroless plating, physical vapor deposition, chemical vapor deposition, thermal evaporation, or electron-beam evaporation of an electrically conducting material such as a metal or a highly-doped semiconductor. In some embodiments, conductive structures 315 may be made of, but are not limited to, copper, zinc, aluminum, or nickel, an alloy composition or other high conductivity materials. Conductive structures 315, also referred to as cathodic conductive structures 315, may extend elevationally through substrate 310 such that conductive structure 315 spans the thickness of substrate 310. In some embodiments, cathodic conductive structures 315 may not extend through substrate 310 such that the height of cathodic conductive structure 315 may be less than thickness of the substrate 310. In some embodiments, cathodic conductive structures 315 may be similar in size and uniformly spaced such that the pitch is uniform. In other embodiments, one or more cathodic conductive structures 315 may be dissimilar in size and may be non-uniformly spaced such that the pitch is non-uniform.

In some embodiments, conductive structures 315 may be coated with dielectric layer 318. For example, the dielectric layer 318 may include an electrically insulating material such as, but not limited to, silicon dioxide, silicon oxynitride, aluminum oxide, hafnium oxide, hafnium silicate, hafnium oxynitride, or other dielectric materials. It is to be appreciated that dielectric materials with a high dielectric constant (high-K) may be desirable to achieve higher capacitance and capacitance density. Dielectric layer 318 may form a conformal coating on the surface of conductive structures 315. In the context of this disclosure, a “conformal” coating refers to a coating that conforms to the contours of a structure that is being coated such that the thickness of the coating is substantially similar at all regions. The thickness of dielectric layer 318 may be in the range of 2 nm to 10 nm, 2 nm to 20 nm, 2 nm to 40 nm, 2 nm to 50 nm, 2 nm to 100 nm, or any suitable thickness based on the application, deposition technique, dielectric material, dielectric constant of the dielectric material, or a combination thereof. In the embodiment shown in FIG. 3A, dielectric layer 318 may include hafnium oxide deposited on conductive structures 315 using an Atomic Layer Deposition (ALD) process. A person of ordinary skill in the art would appreciate that ALD may be used, for example, to deposit thin, conformal coatings of dielectric materials.

Capacitor 350 may further include conductive structures 330 formed on dielectric layer 318. Conductive structures 330, also referred to herein as anodic conductive structures 330, may include a conducting material, such as a metal, and may be formed using a deposition technique including, but not limited to, physical vapor deposition, chemical vapor deposition, thermal evaporation, electron-beam evaporation, doctor-blade coating, dip coating, spray coating, stencil-printing, or other suitable metal deposition or coating processes. In some embodiments, anodic conductive structures 330 may be formed between substrate 310 and dielectric layer 318 such that anodic conductive structures 330 and cathodic conductive structures 315 form an interdigitated capacitor structure, as illustrated in FIG. 3A, separated by dielectric layer 318.

In some embodiments, capacitor 350 may further include a cathode connection formed on a portion of the surface of substrate 310 such that conductive structures 315 may be electrically connected with each other. Cathode connection may function as an electrode contact to apply a voltage signal to conductive structures 315 in a charging or a discharging process of capacitors. In some embodiments, terminal 341 may function as cathode connection. Capacitor 350 may further include an anode connection (not shown) formed on a different portion of the surface of substrate 310 such that conductive structures 330 may be electrically connected with each other. In some embodiments, anode connection may be formed on the same surface or on a different surface from the cathode connection.

In some embodiments, the surface of the anodic conductive structures, or cathodic conductive structures, or both may be textured. The inventors have recognized that one of several challenges in meeting power conversion requirements for mobile communication devices such as smartphones, tablets, and other handheld devices, includes low capacitance due to size limitations and device integration issues. Although the overall capacitance of a power converter may be increased by increasing the size of the capacitor, using a higher dielectric constant material, and/or reducing the distance between the plates, the inventors have recognized that these solutions may either cause a reduction in breakdown voltages, present device integration issues, and/or negatively impact the power conversion efficiency. Therefore, it may be desirable to increase the surface area of the capacitors to increase the capacitance density, which permits increasing power density and integration density. To create additional surface area, in some embodiments, a surface or at least a portion of the surface of conductive structures 315 may be textured. While the underlying interdigitated macro structure may remain the same, texturing may increase the overall surface area, which may allow for higher capacitance density. Operations to texture the surface may include, but are not limited to, mechanical roughening, grinding, sand-casting, laser texturing, dry etching, wet etching, or patterning the surface.

In some embodiments, fabrication of LC network 300 may include, among other steps, bonding individually fabricated inductor 320 and capacitor 350 to form a bonded structure. As mentioned previously, capacitor 350 may be fabricated in a glass substrate (e.g., substrate 310), for example. The capacitor 350 and inductor 320 may be bonded to each other with or without an interfacial layer, using direct bonding, anodic bonding, adhesive bonding, thermocompression bonding, reactive bonding, hybrid bonding, oxide-oxide bonding (e.g., Van der Waals), metal-to-metal (e.g., Cu—Cu diffusion bonding), or other suitable bonding techniques. FIG. 3A illustrates a schematic of the as-bonded structure of LC network 300.

Reference is now made to FIG. 3C, which illustrates a cross-section view of an alternative exemplary LC network 302, consistent with some embodiments of the present disclosure. LC network 302 may be formed without a layer transfer or a bonding process. Fabrication of LC network 302 may include forming an inductor 360, substantially similar to inductor 120 of FIG. 1A, on the glass surface of capacitor 350. Forming the inductor may include forming a planar coil 362 on the glass surface and forming a laminated core 322 substantially similar to laminated core 122 of FIG. 1A on planar coil 362. A dielectric layer 336 may be deposited on at least a portion of laminated core 322 and vias may be etched through dielectric layer to allow formation of one or more electrical contact pads 368. In some embodiments, though not illustrated, thru-vias may be formed through laminated core 322 to provide electrical continuity between planar coil 362 and contact pads 368. Dielectric layer 336 may include a polymer layer, a ceramic layer, or other electrically insulating material.

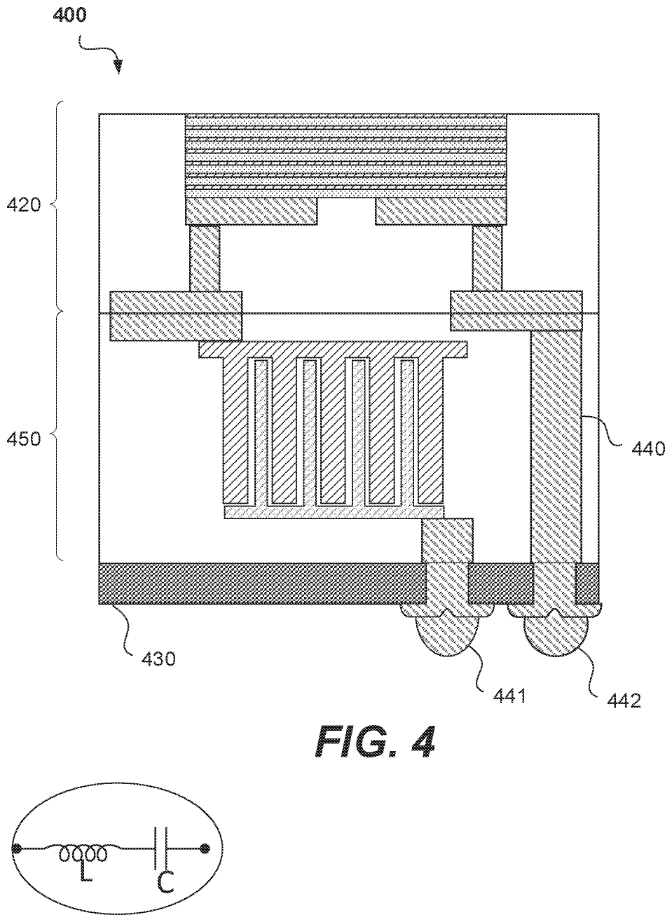

Reference is now made to FIG. 4, which illustrates a cross-section view of an exemplary LC network 400, consistent with some embodiments of the present disclosure. LC network 400 may include an inductor layer 420, a capacitor layer 450, a thru-via 440 configured to enable a series electrical connection of inductor layer 420 with capacitor layer 450, and electrical contact pads 441 and 442.

LC network 400 may be fabricated by bonding a bottom surface of inductor layer 420 to a top surface of capacitor layer 450. In some embodiments, the bonding may include a hybrid bonding such that a metal-to-metal and oxide-to-oxide bond is formed between the bonding surfaces of inductor layer 420 and capacitor layer 450. In some embodiments, thru-via 440 may be etched in capacitor layer 450 and electrical contact pad 442 may be formed to provide an electrical connection to inductor layer 420. In an alternative embodiment, thru-via 440 may be formed in inductor layer 420 and electrical contact pad 442 may be formed thereon. LC network 400 may further include a passivation layer 430 formed on a bottom surface of capacitor layer 450, or on a top surface of inductor layer 420, or both. Passivation layer 430 may include a dielectric layer through which vias may be etched and filled in with an electrically conducting material to provide an electrical connection between external circuitry and one or both, capacitor layer 450 and inductor layer 420. An inset of FIG. 4 illustrates a corresponding circuit representation of the LC network 400.

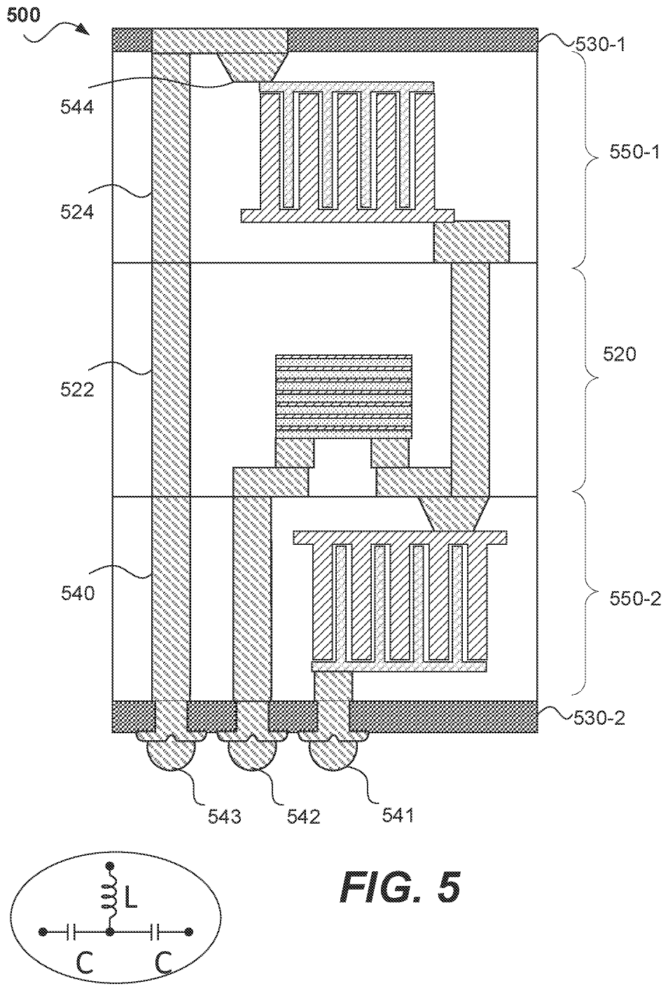

Reference is now made to FIG. 5, which illustrates a cross-section view of an exemplary LC network 500, consistent with some embodiments of the present disclosure. LC network 500 may include an inductor layer 520, two capacitor layers 550-1 and 550-2, passivation layers 530-1 and 530-2, thru-vias 540, 522, and 524, and electrical contact pads 541, 542, and 543. An inset of FIG. 5 illustrates a corresponding circuit representation of the LC network 500. It is to be appreciated that, although not shown, LC network 500 may include one or more inductor layers, two or more capacitor layers, at least one thru-via, and three or more electrical contact pads, as desired. Further, it is to be appreciated that LC network 500 may include an array of inductors and an array of capacitors. The relative arrangement of inductor layers and capacitor layers illustrated in FIG. 5 is a non-limiting example and other arrangements may be possible as well.

In some embodiments, capacitor layer 550-1 and/or capacitor layer 550-2 may be formed by a process described above with reference to FIG. 3A. Fabrication of LC network 500 may include the steps of: (a) bonding a surface (e.g., top surface) of capacitor layer 550-2 to a surface (e.g., bottom surface) of inductor layer 520 to form a first bonded structure, and/or (b) bonding a surface (e.g., bottom surface) of capacitor layer 550-1 to a surface (e.g., top surface) of the first bonded structure to form a second bonded structure. In some embodiments, fabrication of power converter 500 may further include (c) depositing a passivation layer 530-1 or 530-2, on one or both surfaces (e.g., top and bottom surfaces) of the second bonded structure, and/or (d) etching one or more vias in passivation layer 530-1, or 530-2, or both, and/or (e) depositing an electrically conducting material to fill the vias and form electrical contact pads 541, 542, and 543.

In some embodiments, bonding between surfaces of capacitor layers, inductor layers, or capacitor-inductor layers may be formed with or without an interfacial layer, using direct bonding, anodic bonding, adhesive bonding, thermocompression bonding, reactive bonding, hybrid bonding, or other suitable bonding techniques. In some embodiments, capacitor layers 550-1 and 550-2, and inductor layer 520 may comprise one or more thru-vias. As shown in FIG. 5, in an exemplary embodiment, capacitor layer 550-2 may include two thru-vias and a contact via to enable forming electrical contacts on one side of LC network 500 (e.g., the bottom surface). Upon bonding the top surface of capacitor layer 550-2 and the bottom surface of inductor layer 520, at least a portion of a thru-via 522 in inductor layer 520 may be aligned with a thru-via 540 in capacitor layer 550-2. In some embodiments, at least a portion of each of thru-vias 524, 522, and 540 may be aligned allowing an electrical connection between contact pad 543 and contact pad 544 such that a voltage to one or more capacitors of capacitor layer 550-1 may be applied or adjusted.

In some embodiments, one or more electrical contact pads (e.g., electrical contact pad 543) may be formed on a top surface of passivation layer 530-1 and one or more electrical contact pads (e.g., electrical contact pad 541 and 542) may be formed on a bottom surface of passivation layer 530-2 such that electrical contact pad 543 and 541/542 are on the opposite sides. Such a configuration may reduce fabrication process complexity by eliminating one or more process steps to form a thru-via in, for example, inductor layer 520 and capacitor layer 550-2, among other benefits.

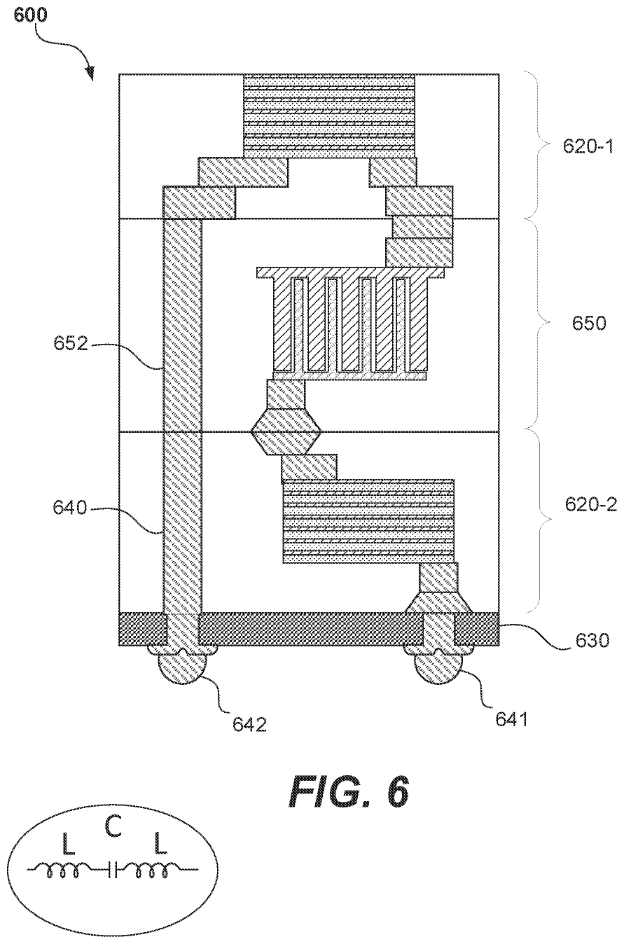

Reference is now made to FIG. 6, which illustrates a cross-section view of an exemplary LC network 600, consistent with some embodiments of the present disclosure. LC network 600 may include two inductor layers 620-1 and 620-2, a capacitor layer 650, a passivation layer 630, thru-vias 640 and 652, and electrical contact pads 641 and 642. An inset of FIG. 6 illustrates a corresponding circuit representation of the LC network having two inductors and a capacitor connected in series. As an example, LC network 600 of FIG. 6 may be used in resonant switched capacitor converters. It is to be appreciated that, although not shown, LC network 600 may include two or more inductor layers, one or more capacitor layers, at least one thru-via, and two or more electrical contact pads, as desired. Further, it is to be appreciated that LC network 600 may include an array of inductors and an array of capacitors. The relative arrangement of inductor layers and capacitor layer illustrated in FIG. 6 is a non-limiting example and other arrangements may be possible as well.

In some embodiments, fabrication of LC network 600 may include the steps of:
(a) bonding a surface (e.g., top surface) of inductor layer 620-2 to a surface (e.g., bottom surface) of capacitor layer 650 to form a first bonded structure, and/or
(b) bonding a surface (e.g., bottom surface) of inductor layer 620-1 to a surface (e.g., a top surface) of the first bonded structure to form a second bonded structure. In some embodiments, fabrication of power converter 600 may further include (c) depositing a passivation layer 630 on a surface (e.g., bottom surface) of inductor layer 620-2,
(d) etching one or more contact vias in passivation layer 630, and/or (e) depositing an electrically conducting material to fill the contact vias and form electrical contact pads 641 and 642. Although not illustrated, in some embodiments, electrical contact pad 642 may be formed on a top surface of inductor layer 620-1 and electrical contact pad 641 may be formed on a bottom surface of passivation layer 630 such that electrical contact pad 641 and 642 are on the opposite sides of power converter 600. Such a configuration may reduce fabrication process complexity by eliminating one or more process steps to form a thru-via 652 in capacitor layer 650, among other benefits.

In some embodiments, bonding between surfaces of capacitor layer(s), inductor layers, or capacitor-inductor layers may be formed with or without an interfacial layer, using direct bonding, anodic bonding, adhesive bonding, thermocompression bonding, reactive bonding, hybrid bonding, or other suitable bonding techniques. In some embodiments, inductor layers 620-1 and 620-2, and capacitor layer 650 may include one or more thru-vias. As shown in FIG. 6, in an exemplary embodiment, inductor layer 620-2 may include thru-via 640 and a contact via to enable forming electrical contacts on the same side of LC network 600 (e.g., the bottom surface of passivation layer 630). Upon bonding the top surface of inductor layer 620-2 and the bottom surface of capacitor layer 650, at least a portion of a thru-via 652 in capacitor layer 650 may be aligned with thru-via 640 in inductor layer 620-2.

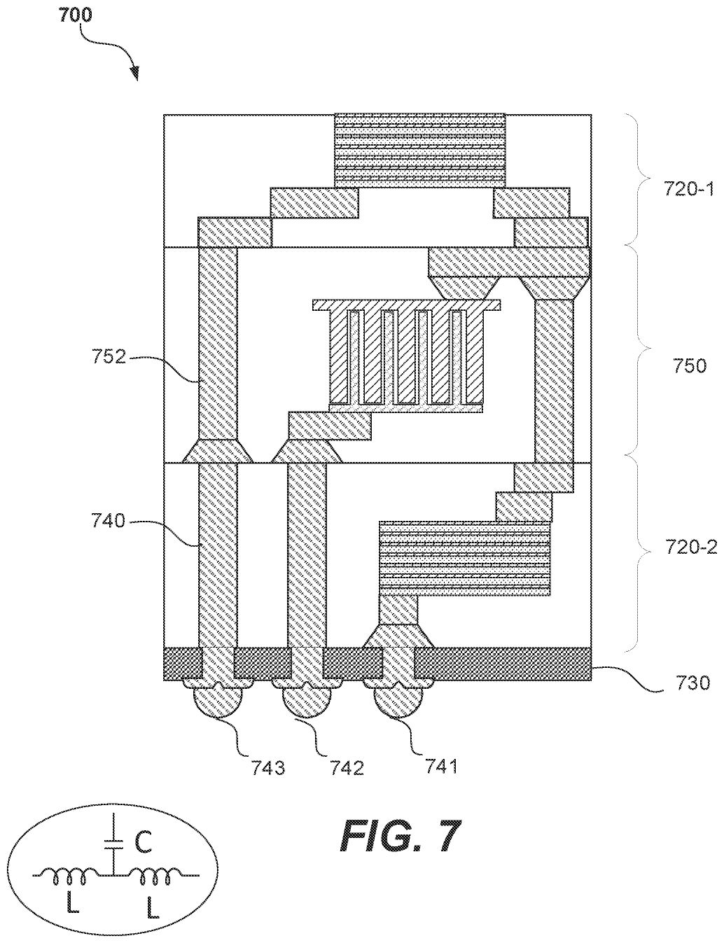

Reference is now made to FIG. 7, which illustrates a cross-section view of an exemplary LC network 700, consistent with some embodiments of the present disclosure. LC network 700 may include two inductor layers 720-1 and 720-2, a capacitor layer 750, a passivation layer 730, thru-vias 740 and 752, and electrical contact pads 741, 742, and 743. An inset of FIG. 7 illustrates a corresponding circuit representation of LC network 700 having two inductors and a capacitor connected in parallel. It is to be appreciated that, although not shown, LC network 700 may include, among other things, two or more inductor layers, one or more capacitor layers, at least one thru-via, and two or more electrical contact pads, as desired. Further, it is to be appreciated that LC network 700 may include an array of inductors and an array of capacitors. The relative arrangement of inductor layers and capacitor layer illustrated in FIG. 7 is a non-limiting example and other arrangements may be possible as well.

In some embodiments, fabrication of LC network 700 may include the steps of:
(a) bonding a surface (e.g., top surface) of inductor layer 720-2 to a surface (e.g., bottom surface) of capacitor layer 750 to form a first bonded structure, and/or
(b) bonding a surface (e.g., bottom surface) of inductor layer 720-1 to a surface (e.g., a top surface) of the first bonded structure to form a second bonded structure. In some embodiments, fabrication of power converter 700 may further include (c) depositing a passivation layer 730 on a surface (e.g., bottom surface) of inductor layer 720-2,
(d) etching one or more contact vias in passivation layer 730, and/or (e) depositing an electrically conducting material to fill the contact vias and thru-vias and form electrical contact pads 741,742, and 743. Although not illustrated, in some embodiments, electrical contact pad 743 may be formed on a top surface of inductor layer 720-1 and electrical contact pads 741 and 742 may be formed on a bottom surface of passivation layer 730 such that electrical contact pads 741 and 742 are on a surface opposite to the surface including electrical contact pad 743. Such a configuration may reduce fabrication process complexity by eliminating one or more process steps to form a thru-via 752 in capacitor layer 750, among other benefits.

In some embodiments, bonding between surfaces of capacitor layer(s), inductor layers, or capacitor-inductor layers may be formed with or without an interfacial layer, using direct bonding, anodic bonding, adhesive bonding, thermocompression bonding, reactive bonding, hybrid bonding, or other suitable bonding techniques. In some embodiments, inductor layers 720-1 and 720-2, and capacitor layer 750 may include, among other things, one or more thru-vias. As shown in FIG. 7, in an exemplary embodiment, inductor layer 720-2 may include thru-via 740 and a contact via to enable forming electrical contacts on the same side of power converter 700 (e.g., the bottom surface of passivation layer 730). Upon bonding the top surface of inductor layer 720-2 and the bottom surface of capacitor layer 750, at least a portion of a thru-via 752 in capacitor layer 750 may be aligned with thru-via 740 in inductor layer 720-2.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures is only for illustrative purposes and is not intended to be limited to any particular sequence of steps. As such, those skilled in the art can appreciate that these steps can be performed in a different order while implementing the same method.

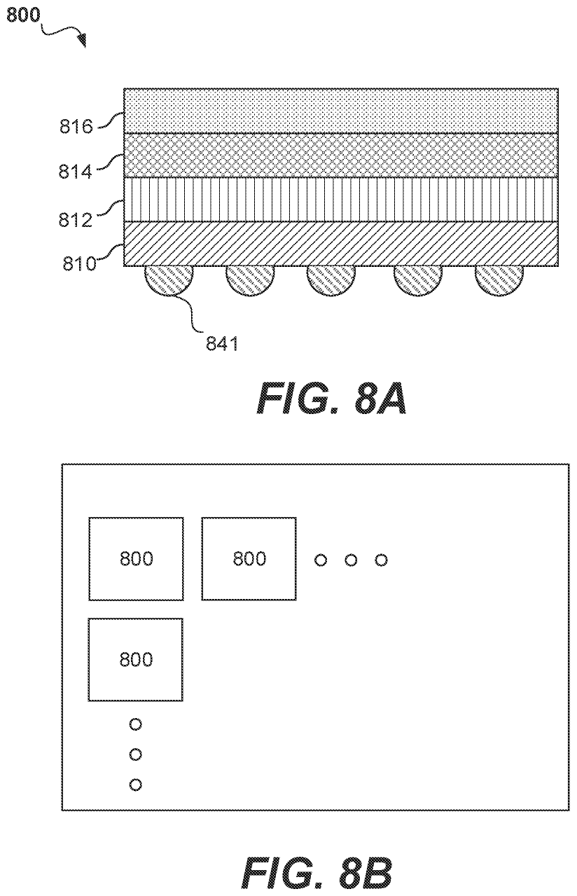

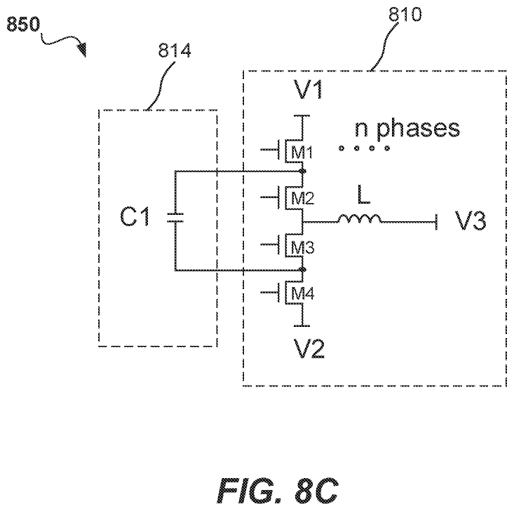

Reference is now made to FIG. 8A, which illustrates a cross-section view of an exemplary power converter 800, in accordance with some embodiments of the present disclosure. Power converter 800 may include a device layer 810, also referred to as a front-end-of-line (FEOL) layer, an interconnect layer 812, also referred to as back-end-of-line (BEOL) layer, a capacitor layer 814, and one or more electrical contact pads 841. Although optional, in the exemplary embodiment shown in FIG. 8A, power converter 800 may further include a handler wafer 816. Although not illustrated, it is to be appreciated that power converter 800 may include more or fewer layers, as appropriate.

In some embodiments, although not shown in FIG. 8A, power converter 800 may include an active device layer including a SOI (Silicon-on-Insulator) substrate, a buried oxide (BOX) layer, and device layer 810. In some embodiments, device layer 810 may include one or more active devices such as, but not limited to, a field effect transistor, a bipolar junction transistor, a diode, or a combination of electrical devices in a circuit capable of performing switching the electrical configuration of capacitors, among other functions. The active devices such as switching elements of device layer 810 may be formed using CMOS compatible semiconductor processing techniques, MEMS techniques, phase change materials (PCM), or a combination thereof. In some embodiments, device layer 810 may include an array of active devices such as a two-dimensional array. In some embodiments, device layer 810 may have a thickness of about 50 μm or less, 40 μm or less, 30 μm or less, 20 μm or less, 10 μm or less, 5 μm or less, or other suitable thickness.

Power converter 800 may comprise interconnect layer 812 or BEOL layer. Interconnect layer 812 may include electrical contacts and/or connections to electrically connect devices between two layers, devices within a layer, devices to an external circuitry, or in some cases even within the same device, through metal lines, for example. In some embodiments, interconnect layer 812 may be formed on device layer 810 such that the number of connections and/or the length of the connection path between devices within device layer 810 or between multiple layers of a device may be shortened, to reduce routing losses or parasitic resistance, for example. The electrical contacts in interconnect layer 812 may be formed of, for example, tungsten (W), or any other suitable conducting material. The connection lines or the paths may be formed of, for example, copper, aluminum, silver, titanium, or a combination thereof, as appropriate.

Power converter 800 may further include capacitor layer 814. In some embodiments, capacitor layer 814 may include an array of capacitors (not shown) formed on a substrate such as, but not limited to, silicon. FIG. 8B illustrates a top plan view of an array of power converters 800 arranged in a rectangular matrix. In some embodiments, power converter 800 may be implemented as a multi-level buck converter (discussed later with reference to FIG. 8C) In some embodiments, capacitor layer 814 may be formed directly on interconnect layer 812 such that the capacitors and active devices of device layer 810 are electrically connected. In some alternative embodiments, capacitor layer 814 may be directly formed or fabricated on device layer 810, without an intermediate interconnect layer 812.

In some embodiments, capacitors of capacitor layer 814 may include stack capacitors, trench capacitors, planar, or lateral capacitors, or a combination thereof. One or more capacitors of capacitor array in capacitor layer 814 may be formed using standard CMOS compatible fabrication techniques and may be integrated with device layer 810 such that the operation of one or more capacitors may be controlled by one or more active devices of device layer 810. In some embodiments, capacitor layer 814 may have a thickness of about 500 μm or less, 400 μm or less, 100 μm or less, 90 μm or less, 80 μm or less, 70 μm or less, 60 μm or less, 50 μm or less, 40 μm or less, 30 μm or less, 20 μm or less, 10 μm or less, 5 μm or less, or other suitable thickness. In some embodiments, more than one capacitor layer 814 may be stacked to form a multi-level capacitor layer. In such a configuration, the thickness of multi-level capacitor layer may be 100 μm or more, 150 μm or more, 200 μm or more, 300 μm or more, 400 μm or more, or any other suitable thickness.

In some embodiments, power converter 800 may optionally include a handler wafer 816, as shown in FIG. 8A. In some embodiments, handler wafer 816 may enable portability and easier processability of a device or a device wafer through fabrication processes. Handler wafer 816 may be bonded, coupled, or attached by an appropriate technique, to power converter 800 and may function as a sacrificial handling wafer, which may be etched, removed, de-bonded, or decoupled upon completion of the fabrication processes of power converter 800.

Reference is now made to FIG. 8C, which illustrates a circuit representation of an exemplary multi-level buck converter 850, in accordance with some embodiments of the present disclosure. An exemplary multi-level buck converter 850 may include switching devices or switches M1, M2, M3, and M4 arranged in a series connection, a capacitor C1, an inductor L, an input voltage V1, and an output voltage V3, and a control/driver circuitry (not illustrated) configured to control switches (e.g. on or off, etc.), for example. A conventional two-level buck power converter may include two metal-oxide silicon field effect transistors (MOSFETs), an inductor, coupled to the input voltage source and an output capacitor. In comparison, a three-level buck power converter, for example, may include additional transistors, a switched inductor, and a capacitor. With respect to the fabrication and spatial arrangement of capacitor C1 and active devices M1-M4 of multi-level buck converter 850, capacitor layer 814 of FIG. 8A may include capacitor C1 or a capacitor array and device layer 810 of FIG. 8A may include active devices M1-M4. In FIG. 8C, corresponding capacitor layer 814 and device layer 810 are indicated by boxes of broken lines.

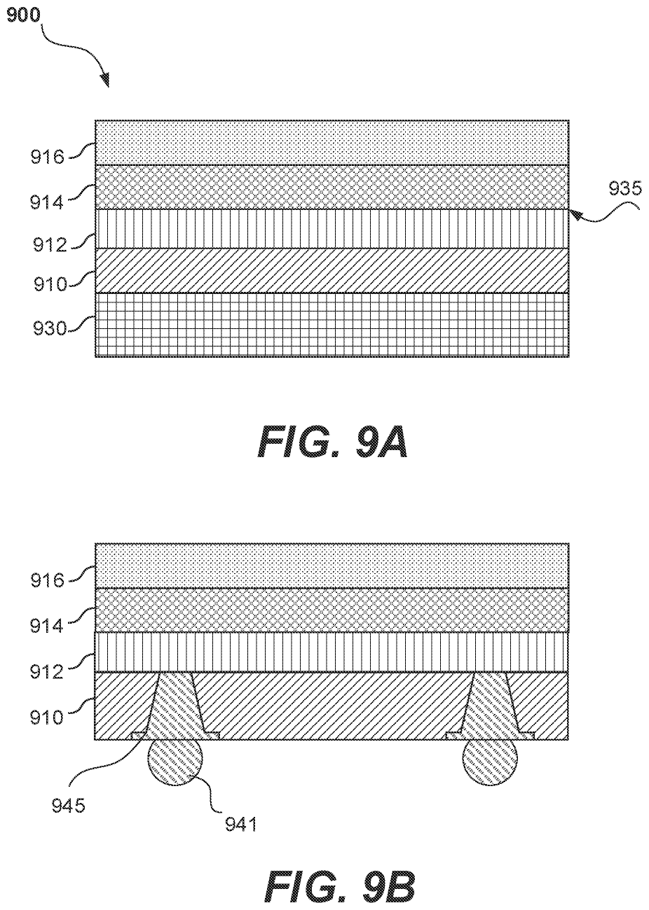

Reference is now made to FIGS. 9A and 9B, which illustrate cross-section views of exemplary power converter 800 through the fabrication steps, in accordance with embodiments of the present disclosure. One of several ways to realize the structure of power converter 800 shown in FIG. 8A may include a single layer transfer (SLT) fabrication technique. A SLT fabrication technique may include one bonding process to form a device or a structure, such as a switched capacitor power converter. It is to be appreciated that steps may be added, removed, reordered, replaced, or modified, as appropriate to form structures having desirable physical and electrical characteristics based on the application and desired product characteristics. The inventors recognized that SLT techniques can be used for fabricating power converters. SLT techniques may be understood to be limited to bonding layers using “sacrificial” or “dumb” substrates. The inventors however recognized, for example, that SLT techniques can be used to bond substrates that include one or more passive devices such as capacitors and inductors, in addition to providing overall structural support, as opposed to only sacrificial or dumb substrates.

With reference to FIG. 9A, which illustrates a structure of power converter 900 comprising a substrate 930, a device layer 910 formed on a surface of substrate 930, a passive device layer including, among other things, a capacitor layer 914, and a handler wafer 916. Substrate 930 may include a SOI wafer which may include a base silicon wafer, a buried oxide layer (BOX) formed on the base silicon layer, and a device-grade silicon layer formed on the BOX layer. Device layer 910 may include active devices (e.g., a CMOS field-effect transistor) configured to control the passive devices or capacitors of capacitor layer 914 of power converter 900. As disclosed herein, device layer 910 may be referred to as a FEOL layer.

Fabricating power converter 900 may include, among other steps, the step of forming capacitor layer 914 on device layer 910. In some embodiments, capacitor layer 914 may be bonded to a top surface of device layer 910 or to a top surface of interconnect layer 912 by a process including, but not limited to, an oxide-oxide bonding, a hybrid bonding, a thermo-compressive bonding, a polymer bonding, a metal-metal bonding, or other suitable bonding techniques. As an example, bond 935 may include a hybrid bond, which includes a metal-to-metal bonding and a dielectric-to-dielectric bonding. Forming a hybrid bond may include, among other steps, depositing a thin dielectric layer on each of the surfaces to be bonded, aligning the surfaces such that the co-planar materials, e.g., metals, are aligned and the surfaces are in physical contact with each other, and annealing, at suitable temperatures, the aligned surfaces to facilitate formation of an oxide-to-oxide and metal-to-metal bond. In the exemplary embodiment shown in FIG. 9A, hybrid bond 935 may be formed between a surface of interconnect layer 912 and capacitor layer 914. In some embodiments, although not shown, hybrid bond 935 may be formed between a surface of device layer 910 and capacitor layer 914.

In some embodiments, capacitor layer 914 formed on a silicon wafer, for example, may be bonded to device layer 910 such that the capacitors, formed on a top surface of the silicon wafer face towards the top surface of device layer 910. In other words, capacitor layer 914 may be “flipped” such that the top surface of capacitor layer 914 comprising the capacitors (e.g., capacitors of FIG. 8B) is bonded to a top surface of device layer 910.

In some embodiments, as shown in FIGS. 9A and 9B, capacitor layer 914 formed on a silicon wafer, for example, may be bonded to interconnect layer 912 such that the capacitors (e.g., capacitors of FIG. 8B), formed on a top surface of the silicon wafer face towards the top surface of interconnect layer 912. In other words, capacitor layer 914 may be “flipped” such that the top surface of capacitor layer 914 comprising the capacitors (e.g., capacitors of FIG. 8B) is bonded to a top surface of interconnect layer 912.

In some embodiments, power converter 900 may include a handler wafer 916, as shown in FIG. 9A. In some embodiments, handler wafer 916 may enable portability and easy processability of a device or a device wafer through fabrication processes. Handler wafer 916 may be bonded, coupled, or attached by an appropriate technique, to power converter 900 and may function as a sacrificial handling wafer, which may be etched, removed, de-bonded, or decoupled upon completion of the fabrication processes of power converter 900, without affecting the structural integrity and performance of power converter 900.

In some embodiments, fabrication of power converter 900 may further include removal of at least a portion of substrate 930 by, for example, mechanical grinding, chemical mechanical polishing, wet etching, dry etching, laser machining, etc. In some embodiments, substrate 930 may be partially or entirely removed such that a bottom surface of device layer 910 may be exposed. Upon complete removal of substrate 930, one or more vias 945 may be formed in device layer 910 and filled in with an electrically conducting material. In some embodiments, an electrical contact pad or a solder bump 941 may be formed on the bottom surface of device layer 910 to facilitate an electrical connection between one or more devices of power converter 900 and external circuitry through interconnects, or between one or more devices of power converter 900. It is to be appreciated that, although only two solder bumps are illustrated in FIG. 9B, any number of solder bumps may be formed to enable electrical connectivity through circuits and devices, as needed.

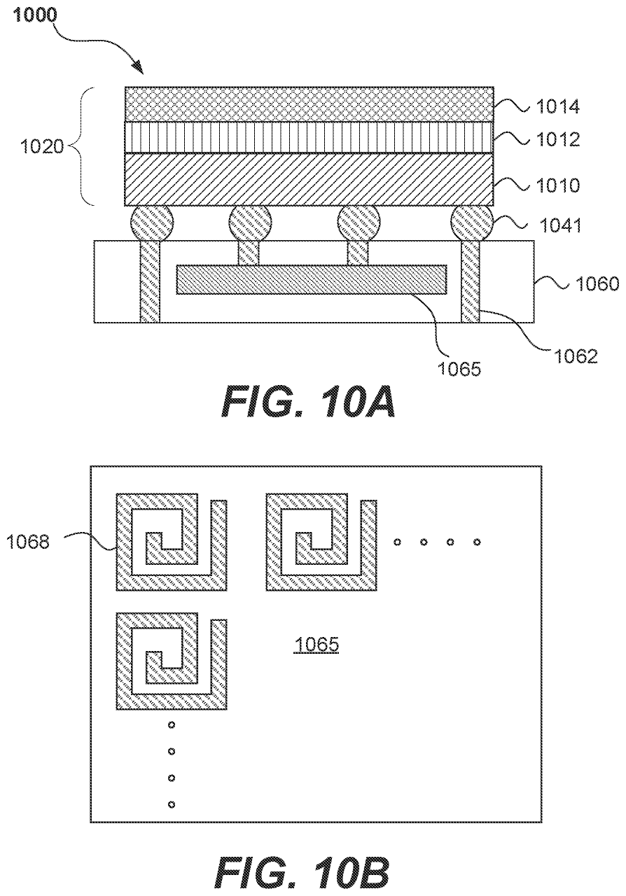

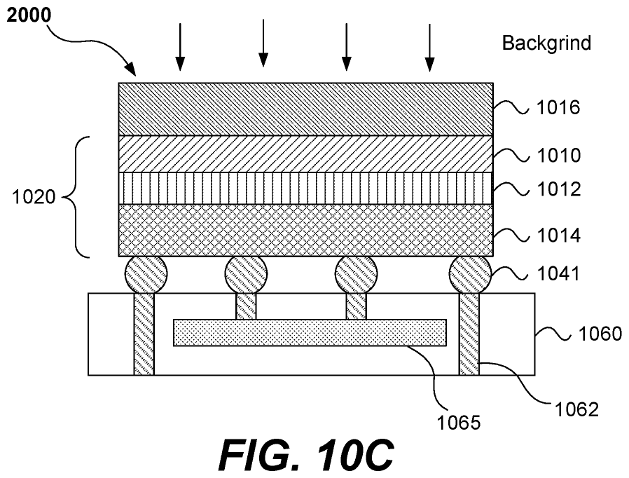

Reference is now made to FIG. 10A, which illustrates a cross-section view of an exemplary power converter 1000, in accordance with some embodiments of the present disclosure. In some embodiments, power converter 1000 may include a device layer 1010, an interconnect layer 1012, a capacitor layer 1014, one or more contact pad 1041, a substrate 1060, an inductor layer 1065, and one or more contact vias 1062.

In some embodiments, substrate 1060 may include a printed circuit board (PCB), in which an inductor layer 1065 may be embedded. In some embodiments, inductor layer 1065 may include an array of inductors 1068, as shown in FIG. 10B, which illustrates a bottom plan view of inductor layer 1065. In some embodiments, inductor 1068 may include a planar inductor, and the array of inductors may include a linear array, or a rectangular array, or any other suitable arrangement. In some embodiments, one or more contact vias 1062 may be formed in substrate 1060 to facilitate electrical connection between inductor layer 1065 and device layer 1010 through electrical contact pads 1041 or between substrate 1060 and device layer 1010, or other device components therein.

In some embodiments, fabrication of power converter may include bonding a structure 1020 including device layer 1010, interconnect layer 1012, and capacitor layer 1014 to substrate 1060 including inductor layer 1065 through one or more contact pads 1041. An exemplary bonding may include, but is not limited to, a metal-metal bonding, hybrid bonding, thermo-compression bonding, a wire bonding, or other suitable bonding techniques configured to form an electrical connection between device layer 1010 and substrate 1060 through aligning one or more contact pads 1041 with at least a portion of one of more contact vias 1062. In some embodiments, fabrication of power converter 1000 may include removal of handler wafer/layer (e.g., handler wafer/layer 916 of FIG. 9A) once the structure 1020 is bonded to substrate 1060.

Reference is now made to FIG. 10C, which illustrates a cross-section view of an exemplary power converter 2000, in accordance with some embodiments of the present disclosure. In some embodiments, power converter 2000 may include a device layer 1010, an interconnect layer 1012, a capacitor layer 1014, a silicon layer 1016, one or more contact pad 1041, a substrate 1060, an inductor layer 1065, and one or more contact vias 1062.

In some embodiments, substrate 1060 may include a printed circuit board (PCB), in which an inductor layer 1065 may be embedded. In some embodiments, inductor layer 1065 may include an array of inductors 1068, as shown in FIG. 10B, which illustrates a bottom plan view of inductor layer 1065. In some embodiments, inductor 1068 may include a planar inductor, and the array of inductors may include a linear array, or a rectangular array, or any other suitable arrangement. In some embodiments, one or more contact vias 1062 may be formed in substrate 1060 to facilitate electrical connection between inductor layer 1065 and device layer 1010 through electrical contact pads 1041 or between substrate 1060 and device layer 1010, or other device components therein.

In some embodiments, fabrication of power converter may include bonding a structure 1020 including device layer 1010, interconnect layer 1012, and capacitor layer 1014 to substrate 1060 including inductor layer 1065 through one or more contact pads 1041. An exemplary bonding may include, but is not limited to, a metal-metal bonding, hybrid bonding, thermo-compression bonding, a wire bonding, or other suitable bonding techniques configured to form an electrical connection between device layer 1010 and substrate 1060 through aligning one or more contact pads 1041 with at least a portion of one of more contact vias 1062. In some embodiments, fabrication of power converter 2000 may include backgrinding silicon layer 1016 once the structure 1020 is bonded to substrate 1060. Before backgrinding the silicon layer 1016, a mold compound or epoxy must be added underneath the one or more contact pads 1041 to provide mechanical support prior to grinding.

As previously mentioned, the inventors have recognized that one of several challenges in satisfying power conversion requirements for portable electronic communication devices may include device integration issues and low structural density because of the large size of devices used to satisfy the overall high capacitance requirement. In addition to providing devices having high power density, high capacitance density, high saturation flux density, and low eddy current losses, wafer-level packaging improvements may further enable higher level of integration. Therefore, it may be desirable to provide systems and methods for wafer-level packaging.

In some embodiments, fan-out wafer-level packaging may be used to provide a smaller package footprint with a larger number of input/output connections, and better thermal and electrical performance. Fan-out wafer-level packaging may include repositioning the product chips on a reconstituted wafer or a substrate before packaging. In some embodiments, a processed wafer may be diced at the start of the process and reconstituted into a standardized wafer such as a carrier wafer or panel. In some embodiments, an adhesive foil may be laminated onto the carrier wafer. The singulated die may be placed face-down on the carrier wafer using a pick and place tool, for example. A compression molding process may be used to encapsulate the die with mold compound while the active face of the die is protected. The mold compound may be cured, and the carrier wafer and adhesive foil may be removed using a de-bonding process resulting in a reconstituted wafer where the mold compound encapsulates the exposed silicon die wafers. The reconstituted wafer may then be processed with standard wafer level packaging techniques for application and patterning of dielectric layers, thin film metals for redistribution and bump soldering. The process of reconstitution of devices may include, but is not limited to, dicing a processed wafer into individual chips including one or more power converters, transferring individual chips from the processed wafer to a carrier wafer and repositioning the transferred chips with a predetermined spacing to allow fan-out of electrical connections outside and away from the core of the chips, reconstituting the carrier wafer using compression molding, for example, to form a reconstituted wafer, and processing the reconstituted wafer with standard wafer level packaging techniques for patterning dielectric layers and forming electrical contacts.

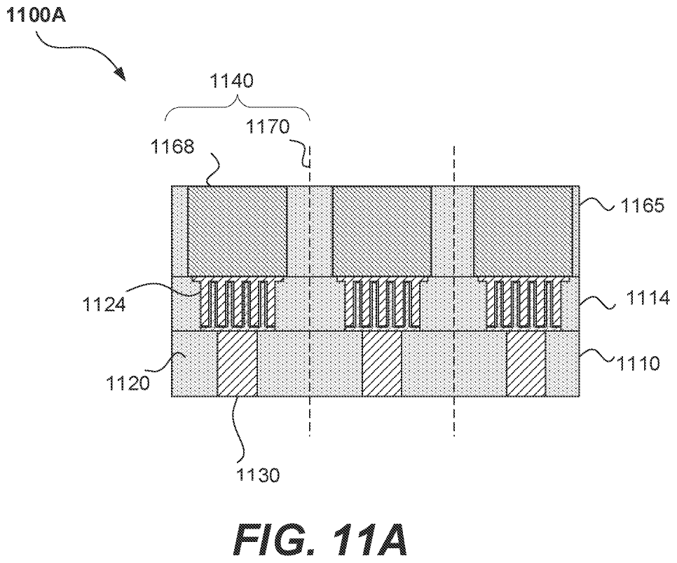

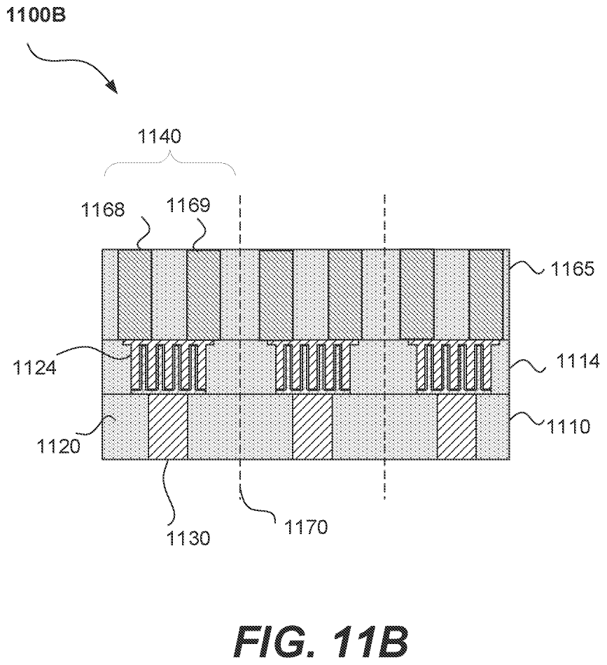

Reference is now made to FIGS. 11A and 11B, which illustrate cross-section views of reconstituted wafers 1100A and 1100B, respectively, in accordance with some embodiments of the present disclosure. As shown, reconstituted wafers 1100A and 1100B may include a reconstituted active device wafer 1110, a reconstituted capacitor wafer 1114, and an inductor array 1165. In some embodiments, although not shown, reconstituted wafers 1100A and 1100B may include a reconstituted active device wafer 1110, a non-reconstituted capacitor array and a non-reconstituted inductor array. In some alternative embodiments, all layers of reconstituted wafers 1100A and 1100B may be reconstituted. It is to be appreciated that any number of permutations and combinations of layer arrangements may be used, as appropriate.

Reconstituted wafers 1100A and 1100B may include mold compound regions 1120 surrounding active devices 1130 in reconstituted active device wafer 1110. In some embodiments, mold compound may include a thermally conductive compound, which may function as a heat spreading material and contribute to transferring heat out of the stacked layers. Mold compound regions 1120 including the thermally conductive mold compound may essentially function as a thermal sink or a thermal via. Reconstituted capacitor wafer 1114 may include a capacitor layer including one or more capacitors 1124 or capacitor arrays. In some embodiments, reconstituted capacitor wafer 1114 may be stacked on top of reconstituted active device wafer 1110. In some embodiments, micro-transfer printing methods may be used for stacking reconstituted capacitor wafer and reconstituted active device wafers. For example, the target wafer in micro-transfer printing may be glass wafer/panel including the capacitors and the source wafer may be a SOI wafer including the active device wafer/panel, or vice versa.

In some embodiments, inductor layer 1165 may be formed on top of reconstituted capacitor wafer 1114. Inductor layer 1165 may include an array of inductors 1168 arranged linearly, or in a two-dimensional array. In some embodiments, inductor layer 1165 may also be reconstituted such that reconstituted wafers 1100A and 1100B comprise a stacked reconstituted structure including reconstituted active device wafer 1110, reconstituted capacitor wafer 1114, and a reconstituted inductor wafer 1165. It is to be appreciated that one or more layers of reconstituted wafers 1100A and 1100B may be formed by reconstituting devices on wafers having desired characteristics.

In some embodiments, a dice line or a scribe line 1170 may be used as a reference guide to dice reconstituted wafers 1110A and 1110B into chips 1140, each chip 1140 including at least an active device 1130 and a passive device (e.g., capacitor 1124 or inductor 1168) controlled by active device 1130. Scribe lines 1170 may be formed away from the active and passive devices to minimize potential damage due to thermal, physical, or mechanical stress. Reconstituted wafers 1100A and 1100B may be scribed and diced along scribe lines 1170, for example, using a wafer laser scribe technique, or other suitable techniques. Although not shown, scribe lines 1170 may be formed horizontally as well as vertically to form a grid pattern of chips, for example. In other embodiments, scribe line 1170, as depicted, may represent that a boundary region suitable for cutting the reconstituted wafer exists between each completed stack of layered components, as opposed to a physical line marked on the wafer.

As illustrated in FIG. 11A, chip 1140 may include an active device 1130, one or more capacitors 1124 and a corresponding inductor 1168. Reconstituted wafer 1100A may include a plurality of chips 1140 that may be spaced apart uniformly or non-uniformly. The reconstituted active device wafer 1110, reconstituted capacitor wafer 1114, and inductor array 1165 may be disposed such that active device 1130, capacitor 1124, and inductor 1168 may be vertically aligned or partially overlapped for efficient space utilization, resulting in improved throughput. Although not illustrated, a chip (e.g., chip 1140) may include one or more capacitor arrays, one or more active devices, or one or more inductors, as appropriate.

In some embodiments, chip 1140 may include, in addition to a capacitor and an active device, one or more corresponding inductors 1168 and 1169, as illustrated in FIG. 11B, which shows a cross-section view of reconstituted wafer 1100B. In some embodiments, a chip may include two or more inductors. In some embodiments, the spacing between inductors may be uniform across inductor array 1165. It is to be appreciated that the spacing between inductors may be non-uniform as well. It is to be further appreciated that the spacing between inductors 1168 and 1169 may be adjustable, based on the desired structure and application. In some embodiments, inductors 1168 and 1169 within a chip may have similar or dissimilar inductance.

In some embodiments, though not illustrated, active devices such as transistors, or other switching elements, that are fabricated on a silicon wafer, may be reconstituted on a panel to enable panel processing of devices. In some embodiments, capacitors and inductors from discretely fabricated capacitor arrays and inductor arrays, respectively, may also be reconstituted on a panel, enabling a panel-level packaging technology.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiment of the specification. Certain features described in the context of various embodiments are not to be considered essential features of those embodiments unless the embodiment is inoperative without those elements.

The embodiments may further be described using the following clauses:
1. A device, comprising:
   an inductor including:
      a first inductor surface and a second inductor surface opposite the first inductor surface;
      a first inductor substrate including a cavity;
      a seed layer formed on a bottom surface of the cavity; and
      a magnetic layer formed on the seed layer, wherein the magnetic layer includes a plurality of stacked magnetic layers separated from each other by an insulating material layer.
2. The device of claim 1, wherein the first inductor substrate comprises an electrically insulating material.
3. The device of claim 2, wherein the electrically insulating material is a ceramic, a polymer, a composite, or a glass.
4. The device of claim 1, further comprising a laminated core and a coil.
5. The device of claim 4, wherein the first inductor substrate supports the coil.
6. The device of claim 5, wherein the coil is made of an electrically conducting material.
7. The device of claim 6, wherein the coil is a spirally wound coil.
8. The device of claim 7, wherein the electrically conducting material is copper, aluminum, silver, titanium, or an alloy.
9. The device of claim 6, wherein the coil is a rectangularly wound coil.
10. The device of claim 9, wherein the electrically conducting material is copper, aluminum, silver, titanium, or an alloy.
11. The device of claim 6, wherein the coil is wound in the shape of a toroid.
12. The device of claim 11, wherein the electrically conducting material is copper, aluminum, silver, titanium, or an alloy.
13. The device of claim 1, wherein the cavity is formed by wet-etching, plasma etching, laser etching, or machining the first inductor substrate.
14. The device of claim 1, wherein the magnetic layer is a nickel-iron alloy or a nickel-cobalt alloy.
15. The device of claim 1, wherein the magnetic layer is formed by electroplating, coating, spraying, doctor-blading, or squeegeeing the magnetic layer.
16 The device of claim 1, wherein the insulating material layer is a dielectric, a polymer, or a ceramic.
17. The device of claim 1, wherein the insulating material layer is formed by coating, spraying, or doctor blading the insulating material layer.
18. The device of claim 1, further comprising:
   a first capacitor, including:
      a first capacitor substrate including a first capacitor surface and a second capacitor surface opposite the first surface;
      a first plurality of conductive structures that extend vertically from the first surface toward the second surface;
      a second plurality of conductive structures that extend vertically from the second surface toward the first surface;
      a first dielectric material physically separating the first and the second plurality of conductive structures, wherein the first and the second plurality of conductive structures are interdigitated;
   wherein the second capacitor surface and the first inductor surface are bonded to each other.
19. The device of claim 18, wherein the first capacitor substrate is glass, photosensitive glass, quartz, silicon, SOI, SOG, SOQ, ceramic, GaAs, or GaN.
20. The device of claim 18, wherein the first capacitor substrate has a thickness ranging from 50 μm to 100 μm.
21. The device of claim 18, wherein the first capacitor substrate has a thickness ranging from 50 μm to 200 μm.
22. The device of claim 18, wherein the first capacitor substrate has a thickness ranging from 50 μm to 300 μm.
23. The device of claim 18, wherein the first capacitor substrate has a thickness ranging from 50 μm to 400 μm.
24. The device of claim 18, wherein the first capacitor substrate has a thickness ranging from 50 μm to 500 μm.
25. The device of claim 18, wherein the first capacitor substrate has a thickness ranging from 50 μm to 1 mm.
26. The device of claim 18, wherein the first and second conductive structures are made of copper, zinc, aluminum, or nickel.
27. The device of claim 18, wherein the first and second conductive structures are the same size and are uniformly spaced.
28. The device of claim 27, wherein the pitch is uniform.
29. The device of claim 18, wherein the first and second conductive structures are the differently sized and are non-uniformly spaced.
30. The device of claim 29, wherein the pitch is non-uniform.
31. The device of claim 18, wherein the first dielectric layer is an electrically insulating material.
32. The device of claim 31, wherein the electrically insulating material is silicon dioxide, silicon oxynitride, aluminum oxide, hafnium oxide, hafnium silicate, or hafnium oxynitride.
33. The device of claim 18, wherein the first dielectric layer has a thickness of 2 nm to 10 nm.
34. The device of claim 18, wherein the first dielectric layer has a thickness of 2 nm to 20 nm.
35. The device of claim 18, wherein the first dielectric layer has a thickness of 2 nm to 40 nm.
36. The device of claim 18, wherein the first dielectric layer has a thickness of 2 nm to 50 nm.
37. The device of claim 18, wherein the first dielectric layer has a thickness of 2 nm to 100 nm.
38. The device of claim 18, wherein the first and second conductive structures are textured to increase the overall surface area.
39. The device of claim 38, wherein the first and second conductive structures are textured to increase the overall surface area by mechanically roughening, grinding, sand-casting, laser texturing, dry etching, wet etching, or patterning the surface.
40. The device of claim 18, wherein the capacitor and the inductor are bonded to each other with an interfacial layer in between the capacitor and the inductor.
41. The device of claim 40, wherein the capacitor and the inductor are bonded to each other using direct bonding, anodic bonding, adhesive bonding, thermocompression bonding, reactive bonding, hybrid bonding, oxide-oxide bonding, or metal-to-metal bonding.
42. The device of claim 18, wherein the capacitor and the inductor are bonded to each other without an interfacial layer in between the capacitor and the inductor.
43. The device of claim 42, wherein the capacitor and the inductor are bonded to each other using direct bonding, anodic bonding, adhesive bonding, thermocompression bonding, reactive bonding, hybrid bonding, oxide-oxide bonding, or metal-to-metal bonding.
44. The device of claim 18, further comprising a first terminal and a second terminal that are located on the same surface of the device and a first thru-via to allow electrical connection to the inductor, a second thru-via to connect the inductor and first capacitor, and a third thru-via to allow electrical connection to the capacitor.
45. The device of claim 44, wherein the third thru-via is etched through the first capacitor substrate.
46. The device of claim 44, wherein the first and second thru-via are etched through the first inductor substrate and second capacitor substrate.
47. The device of claim 44, further comprising a passivation layer on the first capacitor surface.
48. The device of claim 18, further comprising a second capacitor, including:
   a second capacitor substrate including a third capacitor surface and a fourth capacitor surface opposite the third capacitor surface;
      a third plurality of conductive structures that extend vertically from the third capacitor surface toward the fourth capacitor surface;
a fourth plurality of conductive structures that extend vertically from the fourth capacitor surface toward the third capacitor surface;
   a third dielectric material physically separating the third and the fourth plurality of conductive structures, wherein the third and the fourth plurality of conductive structures are interdigitated,
   wherein the second inductor surface and the third capacitor surface are bonded to each other;
   and a first thru-via formed through the first inductor substrate, the first capacitor substrate, and the second capacitor substrate from the fourth capacitor surface to the first capacitor surface to form electrical contacts to the second capacitor, a second thru-via formed through the first capacitor substrate from the second capacitor surface to the first capacitor surface to form electrical contacts to the inductor, a third thru-via formed through the first inductor substrate from the first inductor surface to the second inductor surface to form electrical contacts between the first and second capacitors and the inductor, and a fourth thru-via to enable forming electrical contacts to through the first capacitor surface to the first capacitor.
49. The device of claim 48, further comprising a first passivation layer on the first surface of the device and a second passivation layer on the fourth surface of the device.
50. The device of claim 18, further comprising a second inductor, including:
   a third inductor surface and a fourth inductor surface opposite the third inductor surface;
   a second inductor substrate including a second cavity;
   a second seed layer formed on a bottom surface of the second cavity;
   a second magnetic layer formed on the seed layer, wherein the second magnetic layer includes a plurality of stacked magnetic layers separated from each other by a second insulating material layer;
   and a first thru-via formed through the first inductor substrate, the second inductor substrate, and the first capacitor substrate from the second inductor surface to the third inductor surface to form electrical contacts to the inductor, a second thru-via formed through the first capacitor substrate and the inductor substrate to form electrical contacts between the first capacitor and the inductor, a third thru-via formed through the first capacitor substrate and the second inductor substrate to form electrical contacts between the first capacitor and the second inductor, and a fourth thru-via to enable forming electrical contacts to through the third inductor surface to the second inductor,
   wherein the first capacitor surface and the fourth inductor surface are bonded to each other.
51. The device of claim 50, further comprising a passivation layer on the third inductor surface.
52. The device of claim 18, further comprising a second inductor, including:
   a third inductor surface and a fourth inductor surface opposite the third inductor surface;
   a second inductor substrate including a second cavity;
   a second seed layer formed on a bottom surface of the second cavity;
   a second magnetic layer formed on the seed layer, wherein the second magnetic layer includes a plurality of stacked magnetic layers separated from each other by a second insulating material layer; and
   a first thru-via formed through the first inductor substrate, the second inductor substrate, and the first capacitor substrate from the second inductor surface to the third inductor surface to form electrical contacts to the inductor, a second thru-via formed through the first capacitor substrate and the inductor substrate to form electrical contacts through the third inductor surface to the first capacitor, a third thru-via formed through the first inductor substrate, the second inductor substrate, and the first capacitor substrate to form electrical contacts between the first capacitor, the inductor, and the second inductor, and a fourth thru-via to enable forming electrical contacts to through the third inductor surface to the second inductor,
   wherein the first capacitor surface and the fourth inductor surface are bonded to each other.
53. The device of claim 52, further comprising a passivation layer on the third inductor surface.
54. A power converter, comprising:
   a device layer;
   an interconnect layer; and
   one or more electrical contact pads, wherein a handle layer is removed during fabrication of the power converter.
55. The power converter of claim 54, further comprising:
   a capacitor layer;
   a substrate;
   an inductor layer; and
   one or more contact vias.
56. The power converter of claim 55, wherein the inductor layer comprises an array of inductors and the device layer includes an active device.
57. The power converter of claim 56, wherein the array of inductors are uniformly spaced.
58. The power converter of claim 56, wherein the array of inductors are not uniformly spaced.
59. The power converter of claim 56, wherein the inductor layer comprises one or more inductors.
60. The power converter of claim 59, wherein the one or more of inductors are uniformly spaced.
61. The power converter of claim 59, wherein the one or more inductors are not uniformly spaced.
62. A power converter, comprising:
   a device layer;
   an interconnect layer; and
   one or more electrical contact pads, wherein a wafer of the power converter is back-grinded during fabrication of the power converter and wherein a mold compound or epoxy is added underneath the one or more electrical contact pads during fabrication to provide mechanical support prior to back-grinding.
63. The power converter of claim 62, further comprising:
   a capacitor layer;
   a substrate;
   an inductor layer; and
   one or more contact vias.
64. The power converter of claim 63, wherein the inductor layer comprises an array of inductors and the device layer includes an active device.
65. The power converter of claim 64, wherein the array of inductors are uniformly spaced.
66. The power converter of claim 65, wherein the array of inductors are not uniformly spaced.
67. The power converter of claim 65, wherein the inductor layer comprises one or more inductors.
68 The power converter of claim 67, wherein the one or more of inductors are uniformly spaced.
69. The power converter of claim 68, wherein the one or more inductors are not uniformly spaced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an inductor including:
a first inductor surface and a second inductor surface opposite the first inductor surface;
a first inductor substrate including a cavity;
a seed layer formed on a bottom surface of the cavity; and
a magnetic layer formed on the seed layer, wherein the magnetic layer includes a plurality of stacked magnetic layers separated from each other by an insulating material layer.

2. The device of claim 1, wherein the first inductor substrate comprises an electrically insulating material.

3. The device of claim 2, wherein the electrically insulating material is a ceramic, a polymer, a composite, or a glass.

4. The device of claim 1, further comprising a laminated core and a coil.

5. The device of claim 4, wherein the first inductor substrate supports the coil.

6. The device of claim 5, wherein the coil is made of an electrically conducting material.

7. The device of claim 6, wherein the coil is a spirally wound coil.

8. The device of claim 7, wherein the electrically conducting material is copper, aluminum, silver, titanium, or an alloy.

9. The device of claim 6, wherein the coil is a rectangularly wound coil.

10. The device of claim 9, wherein the electrically conducting material is copper, aluminum, silver, titanium, or an alloy.

11. The device of claim 6, wherein the coil is wound in the shape of a toroid.

12. The device of claim 11, wherein the electrically conducting material is copper, aluminum, silver, titanium, or an alloy.

13. The device of claim 1, wherein the cavity is formed by wet-etching, plasma etching, laser etching, or machining the first inductor substrate.

14. The device of claim 1, wherein the magnetic layer is a nickel-iron alloy or a nickel-cobalt alloy.

15. The device of claim 1, wherein the magnetic layer is formed by electroplating, coating, spraying, doctor-blading, or squeegeeing the magnetic layer.

16. The device of claim 1, wherein the insulating material layer is a dielectric, a polymer, or a ceramic.

17. The device of claim 1, wherein the insulating material layer is formed by coating, spraying, or doctor blading the insulating material layer.

18. The device of claim 1, further comprising:
a first capacitor, including:
a first capacitor substrate including a first capacitor surface and a second capacitor surface opposite the first surface;
a first plurality of conductive structures that extend vertically from the first surface toward the second surface;
a second plurality of conductive structures that extend vertically from the second surface toward the first surface;
a first dielectric material physically separating the first and the second plurality of conductive structures, wherein the first and the second plurality of conductive structures are interdigitated;
wherein the second capacitor surface and the first inductor surface are bonded to each other.

19. The device of claim 18, wherein the first capacitor substrate is glass, photosensitive glass, quartz, silicon, SOI, SOG, SOQ, ceramic, GaAs, or GaN.

20. The device of claim 18, wherein the first capacitor substrate has a thickness ranging from 50 μm to 100 μm.

21. The device of claim 18, wherein the first capacitor substrate has a thickness ranging from 50 μm to 200 μm.

22. The device of claim 18, wherein the first capacitor substrate has a thickness ranging from 50 μm to 300 μm.

23. The device of claim 18, wherein the first capacitor substrate has a thickness ranging from 50 μm to 400 μm.

24. The device of claim 18, wherein the first capacitor substrate has a thickness ranging from 50 μm to 500 μm.

25. The device of claim 18, wherein the first capacitor substrate has a thickness ranging from 50 μm to 1 mm.

26. The device of claim 18, wherein the first and second conductive structures are made of copper, zinc, aluminum, or nickel.

27. The device of claim 18, wherein the first and second conductive structures are the same size and are uniformly spaced.

28. The device of claim 27, wherein the pitch is uniform.

29. The device of claim 18, wherein the first and second conductive structures are the differently sized and are non-uniformly spaced.

30. The device of claim 29, wherein the pitch is non-uniform.

31. The device of claim 18, wherein the first dielectric layer is an electrically insulating material.

32. The device of claim 31, wherein the electrically insulating material is silicon dioxide, silicon oxynitride, aluminum oxide, hafnium oxide, hafnium silicate, or hafnium oxynitride.

33. The device of claim 18, wherein the first dielectric layer has a thickness of 2 nm to 10 nm.

34. The device of claim 18, wherein the first dielectric layer has a thickness of 2 nm to 20 nm.

35. The device of claim 18, wherein the first dielectric layer has a thickness of 2 nm to 40 nm.

36. The device of claim 18, wherein the first dielectric layer has a thickness of 2 nm to 50 nm.

37. The device of claim 18, wherein the first dielectric layer has a thickness of 2 nm to 100 nm.

38. The device of claim 18, wherein the first and second conductive structures are textured to increase the overall surface area.

39. The device of claim 38, wherein the first and second conductive structures are textured to increase the overall surface area by mechanically roughening, grinding, sand-casting, laser texturing, dry etching, wet etching, or patterning the surface.

40. The device of claim 18, wherein the capacitor and the inductor are bonded to each other with an interfacial layer in between the capacitor and the inductor.

41. The device of claim 40, wherein the capacitor and the inductor are bonded to each other using direct bonding, anodic bonding, adhesive bonding, thermocompression bonding, reactive bonding, hybrid bonding, oxide-oxide bonding, or metal-to-metal bonding.

42. The device of claim 18, wherein the capacitor and the inductor are bonded to each other without an interfacial layer in between the capacitor and the inductor.

43. The device of claim 42, wherein the capacitor and the inductor are bonded to each other using direct bonding, anodic bonding, adhesive bonding, thermocompression bonding, reactive bonding, hybrid bonding, oxide-oxide bonding, or metal-to-metal bonding.

44. The device of claim 18, further comprising a first terminal and a second terminal that are located on the same surface of the device and a first thru-via to allow electrical connection to the inductor, a second thru-via to connect the inductor and first capacitor, and a third thru-via to allow electrical connection to the capacitor.

45. The device of claim 44, wherein the third thru-via is etched through the first capacitor substrate.

46. The device of claim 44, wherein the first and second thru-via are etched through the first inductor substrate and second capacitor substrate.

47. The device of claim 44, further comprising a passivation layer on the first capacitor surface.

48. The device of claim 18, further comprising a second capacitor, including:
a second capacitor substrate including a third capacitor surface and a fourth capacitor surface opposite the third capacitor surface;
a third plurality of conductive structures that extend vertically from the third capacitor surface toward the fourth capacitor surface;
a fourth plurality of conductive structures that extend vertically from the fourth capacitor surface toward the third capacitor surface;
a third dielectric material physically separating the third and the fourth plurality of conductive structures, wherein the third and the fourth plurality of conductive structures are interdigitated,
wherein the second inductor surface and the third capacitor surface are bonded to each other;
and a first thru-via formed through the first inductor substrate, the first capacitor substrate, and the second capacitor substrate from the fourth capacitor surface to the first capacitor surface to form electrical contacts to the second capacitor, a second thru-via formed through the first capacitor substrate from the second capacitor surface to the first capacitor surface to form electrical contacts to the inductor, a third thru-via formed through the first inductor substrate from the first inductor surface to the second inductor surface to form electrical contacts between the first and second capacitors and the inductor, and a fourth thru-via to enable forming electrical contacts to through the first capacitor surface to the first capacitor.

49. The device of claim 48, further comprising a first passivation layer on the first surface of the device and a second passivation layer on the fourth surface of the device.

50. The device of claim 18, further comprising a second inductor, including:
a third inductor surface and a fourth inductor surface opposite the third inductor surface;
a second inductor substrate including a second cavity;
a second seed layer formed on a bottom surface of the second cavity;
a second magnetic layer formed on the seed layer, wherein the second magnetic layer includes a plurality of stacked magnetic layers separated from each other by a second insulating material layer;
and a first thru-via formed through the first inductor substrate, the second inductor substrate, and the first capacitor substrate from the second inductor surface to the third inductor surface to form electrical contacts to the inductor, a second thru-via formed through the first capacitor substrate and the inductor substrate to form electrical contacts between the first capacitor and the inductor, a third thru-via formed through the first capacitor substrate and the second inductor substrate to form electrical contacts between the first capacitor and the second inductor, and a fourth thru-via to enable forming electrical contacts to through the third inductor surface to the second inductor,
wherein the first capacitor surface and the fourth inductor surface are bonded to each other.

51. The device of claim 50, further comprising a passivation layer on the third inductor surface.

52. The device of claim 18, further comprising a second inductor, including:
a third inductor surface and a fourth inductor surface opposite the third inductor surface;
a second inductor substrate including a second cavity;
a second seed layer formed on a bottom surface of the second cavity;
a second magnetic layer formed on the seed layer, wherein the second magnetic layer includes a plurality of stacked magnetic layers separated from each other by a second insulating material layer; and
a first thru-via formed through the first inductor substrate, the second inductor substrate, and the first capacitor substrate from the second inductor surface to the third inductor surface to form electrical contacts to the inductor, a second thru-via formed through the first capacitor substrate and the inductor substrate to form electrical contacts through the third inductor surface to the first capacitor, a third thru-via formed through the first inductor substrate, the second inductor substrate, and the first capacitor substrate to form electrical contacts between the first capacitor, the inductor, and the second inductor, and a fourth thru-via to enable forming electrical contacts to through the third inductor surface to the second inductor,
wherein the first capacitor surface and the fourth inductor surface are bonded to each other.

53. The device of claim 52, further comprising a passivation layer on the third inductor surface.

54. A power converter, comprising:
a device layer;
an interconnect layer; and
one or more electrical contact pads, wherein a handle layer is removed during fabrication of the power converter.

55. The power converter of claim 54, further comprising:
a capacitor layer;
a substrate;
an inductor layer; and
one or more contact vias.

56. The power converter of claim 55, wherein the inductor layer comprises an array of inductors and the device layer includes an active device.

57. The power converter of claim 56, wherein the array of inductors are uniformly spaced.

58. The power converter of claim 56, wherein the array of inductors are not uniformly spaced.

59. The power converter of claim 56, wherein the inductor layer comprises one or more inductors.

60. The power converter of claim 59, wherein the one or more of inductors are uniformly spaced.

61. The power converter of claim 59, wherein the one or more inductors are not uniformly spaced.

62. A power converter, comprising:
a device layer;
an interconnect layer; and
one or more electrical contact pads, wherein a wafer of the power converter is back-grinded during fabrication of the power converter and wherein a mold compound or epoxy is added underneath the one or more electrical contact pads during fabrication to provide mechanical support prior to back-grinding.

63. The power converter of claim 62, further comprising:
a capacitor layer;
a substrate;
an inductor layer; and
one or more contact vias.

64. The power converter of claim 63, wherein the inductor layer comprises an array of inductors and the device layer includes an active device.

65. The power converter of claim 64, wherein the array of inductors are uniformly spaced.

66. The power converter of claim 65, wherein the array of inductors are not uniformly spaced.

67. The power converter of claim 65, wherein the inductor layer comprises one or more inductors.

68. The power converter of claim 67, wherein the one or more of inductors are uniformly spaced.

69. The power converter of claim 68, wherein the one or more inductors are not uniformly spaced.
